(19) United States
(12) Patent Application Publication
(10) Pub. No.: US 2024/0407142 A1
(43) Pub. Date: Dec. 5, 2024

(54) HYBRID AND ADAPTIVE COOLING MECHANISMS

(71) Applicant: INTEL CORPORATION, SANTA CLARA, CA (US)

(72) Inventors: Francesc Guim Bernat, Barcelona (ES); Karthik Kumar, Chandler, AZ (US); Uzair Qureshi, Chandler, AZ (US); Marcos Carranza, Portland, OR (US); Marek Piotrowski, Pepowo (PL)

(73) Assignee: INTEL CORPORATION, SANTA CLARA, CA (US)

(21) Appl. No.: 18/799,263

(22) Filed: Aug. 9, 2024

(51) Int. Cl. H05K 7/20

(52) U.S. Cl. CPC H05K 7/20836

(57) ABSTRACT

Hybrid and adaptive cooling systems are described. A method comprises selecting a cooling system type from a set of cooling system types of a hybrid cooling system to cool an electronic component of an electronic device, generating a control directive to activate a cooling component of the cooling system type, and performing thermal management of the electronic component of the electronic device using the cooling component of the cooling system type. Other embodiments are described and claimed.

### BACKGROUND

The increased growth and sophistication of artificial intelligence (AI) have driven design of larger and more powerful processors to manage the demands of large-scale language training programs required by AI developers. For example, semiconductor chips may contain billions of transistors (e.g., fin field-effect (FinFET) transistors) with decreasing die sizes that can execute tera floating point operations per second (TFLOP) of performance. With the increased demand for AI and the vast amounts of data needed to build AI services coupled with the increasing volume of data generated by other sources, such as edge computing and sixth generation (6G) cellular networks, the need for sustainable and scalable compute and storage solutions is becoming more urgent. However, an increase in data center capacity to fill this need is also resulting in an increase in energy consumption. This increase in data center energy demand is testing the limits of legacy thermal technologies. Effectively and efficiently cooling these chips presents new thermal challenges for legacy cooling technologies.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a system in accordance with one embodiment.

FIG. 2 illustrates a cooling system in accordance with one embodiment.

FIG. 3 illustrates an apparatus in accordance with one embodiment.

FIG. 4 illustrates a logic diagram in accordance with one embodiment.

FIG. 5 illustrates a logic diagram in accordance with one embodiment.

FIG. 6 illustrates a logic diagram in accordance with one embodiment.

FIG. 7 illustrates a logic diagram in accordance with one embodiment.

FIG. 8 illustrates a logic diagram in accordance with one embodiment.

FIG. 9 illustrates a logic diagram in accordance with one embodiment.

FIG. 10 illustrates a system in accordance with one embodiment.

FIG. 11 illustrates an apparatus in accordance with one embodiment.

FIG. 12 illustrates a logic flow in accordance with one embodiment.

FIG. 13 illustrates a computer-readable storage medium in accordance with one embodiment.

FIG. 14 illustrates a computing architecture in accordance with one embodiment.

FIG. 15 illustrates a communications architecture in accordance with one embodiment.

### DETAILED DESCRIPTION

Embodiments generally relate to cooling techniques for thermal management of electronic devices such as semiconductor devices. Embodiments particularly relate to a hybrid cooling architecture for electronic devices for implementation in larger electronic devices, platforms or systems, such as server blades for a server rack of a data center to provide computing and storage services.

Data centers are complex systems in which multiple technologies and pieces of hardware interact to maintain safe and continuous operation of servers. With so many systems requiring power, the electrical energy used generates thermal energy. As the center operates, this heat builds and, unless removed, can cause equipment failures, system shutdowns, and physical damage to components. Much of this increased heat can be attributed to different processing units, collectively referred to as an “XPU,” where X stands for different letters depending on the context or specific function of the processing unit, which represents a shift towards more specialized, task-specific processors. Examples of an XPU include a central processing unit (CPU), graphics processing unit (GPU), data processing unit (DPU), vision processing unit (VPU), neural processing unit (NPU), infrastructure processing unit (IPU), tensor processing unit (TPU), and other processing units. Each new generation of XPU processor seems to offer greater speed, functionality, and storage, and chips are being asked to carry more of the load.

An increasingly urgent challenge is to find a new approach to cooling data centers that reaches beyond legacy thermal technologies, that is both energy-efficient and scalable, with the ultimate goal of enabling greater compute and data storage in an energy-efficient context. Effective operation of any processor depends on temperatures remaining within designated thresholds. The more power an XPU uses, the hotter it becomes. When a component approaches its maximum temperature, a device may attempt to cool the processor by lowering its frequency or throttling it. While effective in the short term, repeated throttling can have negative effects, such as shortening the life of the component.

A potential thermal management approach for cooling data centers is referred to as liquid cooling. Examples of liquid cooling techniques include direct-to-chip (DTC) cooling and liquid immersion cooling. DTC cooling manages heat through the direct application of a coolant liquid onto the heat-generating components, such as processors and memory units. Unlike traditional air cooling that uses fans to circulate air around these components, DTC cooling involves circulating a coolant through a closed loop that absorbs heat directly from the components. This process significantly enhances cooling efficiency because liquids generally have higher heat capacity and conductivity than air. In DTC cooling systems, the coolant is pumped through cold plates that are in direct or indirect contact with the components. The heat from the components is transferred to the coolant. It is then circulated away and cooled through a heat exchanger. This method allows for more effective heat dissipation, enabling higher performance, increased component density, and potentially quieter operation due to the reduced need for fans. DTC cooling is particularly beneficial in high-performance computing environments, like data centers and servers, as well as in high-end gaming personal computers and workstations, where the heat generated can exceed the capabilities of traditional air cooling methods.

In liquid immersion cooling systems, an immersion tank is filled with a dielectric fluid that partially or fully covers electronic components. The fluid dissipates heat generated by the electronic components. In open bath systems, an immersion tank is covered or uncovered and operates at atmospheric pressure. In closed bath systems, an immersion tank seals off the immersion fluid from the environment. The electronic components are fully submerged in a thermally conductive, electrically non-conductive liquid within a sealed enclosure. The closed bath immersion tank prevents the cooling liquid from coming into contact with the external environment. This enclosure helps in maintaining the integrity and cleanliness of the liquid, preventing contamination and evaporation.

As compute demand has grown significantly, particularly with generative AI usage driving very heavy workloads for compute and memory subsystems, so has the power consumption and associated thermals for the platform. Currently, a lot of effort and innovation goes into cooling solutions that are designed for the platform. However, these solutions are pre-established with static configurations that are not changed after deployment. For example, an immersion cooling system architecture is typically designed upfront for a given electronic device or electronic system, and the cooling elements are statically placed.

While the obvious advantage of an a priori cooling system design is simplicity, and uniformity, there are several challenges emerging with such a solution in emerging data centers. For example, systems have different and varying requirements depending on usage, deployment location, environmental conditions, and so forth. Designing the entire cooling solution statically upfront for a worst case scenario is severely limiting and often constrains the system in terms of power, far beyond what might be possible at a component level. This in turn can hurt performance and capability, due to different components being stressed differently depending on the workload. Further, current systems are increasingly configurable with varying XPUs. As requirements change and usage patterns change, system configurations can also change. For example, a system can add an accelerator or swap out memory units. However, when the cooling solution is designed a priori to be static, changing the configuration can be extremely limiting and require iteration to a factory process. This can be prohibitively expensive, inefficient, or limit performance.

As compute demands continue to grow, especially with the increasing prevalence of accelerators and GPUs for generative AI solutions, thermal constraints emerge as a significant bottleneck for system and server rack design. This in turn, has placed a sharp emphasis on cooling solutions to manage this power consumption. In current data centers, all the cooling systems act as independent entities that operate cooling mechanisms to maintain a certain temperature target. However, workloads and use cases do not always require a constant energy efficiency or performance. Therefore, cooling requirements for a system will change over time, depending on factors such as the phases of the workload, overall load on the system, priority levels, or service level objectives (SLO). Further, system resources consumed by the varying workloads may also change over time. For example, machine learning (ML) models such as large language models (LLMs) operate in two phases. The first phase is a time to first token. The second phase is an average time for a remainder of the tokens. Unlike the first phase, the second phase is completely memory bandwidth bound, and exercises significant power (and thermal stress) on the memory subsystem. However, this phenomena is not observed in the first phase. Conventional cooling solutions implement static cooling solutions that cannot adapt to different operational phases of software and hardware.

Architecting cooling solutions for emerging systems comes with additional technical challenges. For example, ambient temperatures can fluctuate greatly across the year, and in edge deployments, this can greatly impact the design of the cooling solution for the server. As an illustration, the difference in the average high temperatures in many cities, such as Phoenix and Chicago, is as much as 40 to 50 degrees Fahrenheit (F). This fluctuation makes it difficult to implement a single cooling solution for the server. Further, different cooling solutions vary in setup costs, operational costs, and space requirements depending on a type of server. For example, assume a general server uses air cooling. The general server may have a power usage effectiveness (PUE) of 1.66 watts (W) for air cooling, a thermal design power (TDP) of 500 W, fan space requirements, low initial setup costs, and high operational costs. By comparison, an AI server using air cooling may have a PUE of 1.66 W a TDP of 800-1000 W, fan space requirements, low initial setup costs, and high operational costs. Further, an AI server using open liquid cooling may have a PUE of 1.1-1.3 W a TDP of 1500 W, open liquid cooling structures, high initial setup costs, and low operational costs. Similarly, an AI server using immersive liquid cooling may have a PUE of 1.02-1.05 W a TDP of 1500 W and above, closed liquid cooling structures, high initial setup costs, and low operational costs. These varying parameters make a single cooling solution difficult to design for all systems in all operating environments. In general, single phase immersion cooling has the best performance, but it comes with high operational costs. Likewise, air cooling has low operational costs but it may not be sufficient for all operating conditions, for example, when the ambient temperature is too high. As a result, current designs provision for the worst case temperatures in a deployment model, and therefore they are wasteful in terms of operational cost. Unfortunately, current systems do not have mechanisms for system administrators to switch back and forth between different cooling solutions, or to deploy adaptively hybrid cooling solutions that utilize an adaptive combination of different solutions. For example, consider the scenario where during the summer in Chicago, an edge server requires liquid immersion cooling in order to be able to support a given set of workloads. However, in winter in Chicago, an edge server is already exposed to ambient temperatures that are very cold, and a simple fan based cooling mechanism would be sufficient.

Embodiments solve these and other challenges using a hybrid cooling system for an electronic device, such as a server blade in a server rack for a data center or edge system, for example. The hybrid cooling system utilizes a combination of different cooling subsystems, such as an air cooling subsystem, a liquid cooling subsystem, a DTC cooling subsystem, an open liquid cooling subsystem, an immersion liquid cooling subsystem, and so forth. The hybrid cooling system may include a hybrid cooling controller to dynamically control an amount of resources provided to each of the different cooling subsystems, or switch between different cooling systems, to precisely control delivery of a defined level of cooling needed by the electronic device. The hybrid cooling controller dynamically adjusts distribution of cooling resources provided by the hybrid cooling system in response to changes in operating conditions for the electronic device. The hybrid cooling system is designed for a worst-case scenario and the hybrid cooling controller activates, deactivates, or otherwise controls the cooling subsystems on an as-needed or on-demand basis. For example, the hybrid cooling controller may activate the air cooling subsystem in spring and winter seasons and deactivate the liquid cooling subsystem, and activate the liquid cooling subsystem in summer and fall seasons and deactivate the air cooling system. In some cases, the hybrid cooling controller partially activates or partially deactivates cooling subsystems to obtain a balanced amount of cooling from the cooling subsystems. Further, the hybrid cooling controller can automatically control delivery of cooling within a device chassis to ensure proper cooling of electronic components within the device chassis in accordance with various cooling policies, such as service level objectives (SLOs) defined by service level agreements (SLAs) associated with the electronic components and/or cooling zones for the electronic components.

Some embodiments are particularly directed to precision delivery of cooling and power resources across different parts of an electronic device. In one embodiment, for example, an electronic device is divided into one or more cooling zones. A cooling zone is a defined spatial area within a device chassis. The defined spatial area may be a two-dimensional (2D) area or a three-dimensional (3D) area within the device chassis. Each cooling zone includes one or more electronic components. For example, a first cooling zone includes a power supply, a second cooling zone includes semiconductor devices mounted on a printed circuit board (PCB), a third cooling zone includes a storage device, a fourth cooling zone includes a network interface card (NIC), and so forth. Each cooling zone includes one or more sensors. The hybrid cooling controller may control the different cooling subsystems of the hybrid cooling system to deliver precision cooling to the electronic components within the different cooling zones based on sensor data, instantaneous workloads of the electronic components, or predicted workloads for the electronic components. For example, the hybrid cooling controller increases or decreases distribution of system resources, such as an amount of cooling or power from a cooling budget or a power budget, in response to changes in current workloads of the electronic components, future workloads of the electronic components, updated cooling zones, updated configuration data for cooling zones, availability of system resources, co-orchestration with other electronic devices (e.g., in a server farm), and other component-level or system-level parameters.

Further, the hybrid cooling system may utilize or have access to an AI system to assist in managing cooling operations. The AI system may implement one or more machine learning (ML) algorithms to train one or more ML models. For example, an ML model may receive as input configuration data for the hybrid cooling system and cooling subsystems, and generate one or more metrics for the hybrid cooling system or cooling subsystem based on the configuration data. The configuration data may comprise a set of system parameters or system rules (e.g., cooling policies, orchestration policies, etc.) associated with the hybrid cooling system, such as cooling subsystems, electronic components, electronic devices, electronic systems, networks, and so forth. Non-limiting examples of parameters include parameters with values representing an amount of cooling fluid, a type of cooling fluid, a velocity of movement of the cooling fluid, an amount of power for a cooling subsystem, an amount of cooling capacity for a cooling subsystem, and so forth. The ML model may analyze the set of parameters, and it generates a metric for the hybrid cooling system based on the set of parameters. Non-limiting examples of metrics include measurement values, key performance indicators (KPIs), operational metrics, system metrics, and so forth. For example, a metric may comprise measurement values representing aging of system components, resource utilization, system energy efficiency, system workloads, operating conditions, environment conditions, ambient conditions, service level objectives against workloads, and so forth. The AI system may modify the various system parameters to the hybrid cooling system to observe effects on the hybrid cooling system through changes to the metrics. Through a series of iterations, the AI system converges on a set of system parameters optimized for the hybrid cooling system. The AI system uses the system parameters to update cooling policies for the hybrid cooling system. The ML model, system parameters, and/or cooling policies can be shared with other hybrid cooling systems through a federated system using, for example, peer-to-peer (P2P) communications through a public or private network.

The embodiments provide several technical advantages relative to conventional cooling systems. For example, conventional cooling solutions and cooling policies are typically pre-established with a static configuration that can never be changed. Therefore, an original equipment manufacturer (OEM) must design and configure a conventional cooling solution for a system prior to deployment. Embodiments implement a hybrid cooling system with multiple cooling subsystems and dynamic policies to provide flexibility in system network design. A system logs telemetry data with the help of a set of smart temperature sensors. These sensors in turn are queryable and exposed to system administrators via application programming interfaces (APIs), in addition to being used by the system itself to understand current thermal profiles, cooling adequacy, and cooling capacity for deployed cooling solutions. This gives the system visibility into how much cooling capacity is available across a spatial profile in a given server. Further, the system dynamically adapts the cooling capability in response to thermal needs of a system or sub-system. For example, the system could use different types of cooling technologies without having to go back to the factory for a redesign. In addition, embodiments recognize that workload resource requirements change over time, and learn to recognize changes in execution phases and communicate these phase changes to a centralized cooling infrastructure. Embodiments perform precision cooling that is co-orchestrated with software and hardware system requirements. Embodiments implement a set of APIS to adapt cooling per cooling zones depending on SLOs and SLAs. Embodiments adaptively distribute, control, and deliver power and cooling across different parts of a system or subsystem. Embodiments use a network of sensors to monitor a set of metrics associated with electronic components, such as XPU metrics like floating point operations (FLOPS) or clocks per instruction. Embodiments use this information to implement a closed loop power and liquid cooling intelligent infrastructure. For example, embodiments may implement a definition such as X FLOPS at Y Watts requires Z degrees C. water or immersion liquid, with an incremental increase equation identified and maintained by the hardware or software, on a per-component basis within a server chassis or server rack. Other technical advantages exist as well. Embodiments are not limited to these examples.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), fifth generation (5G) and sixth generation (6G) communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages having cold plates and manifolds over package substrates that have a plurality of semiconductor dies, where each semiconductor die is cooled with one or more liquid cooling paths.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

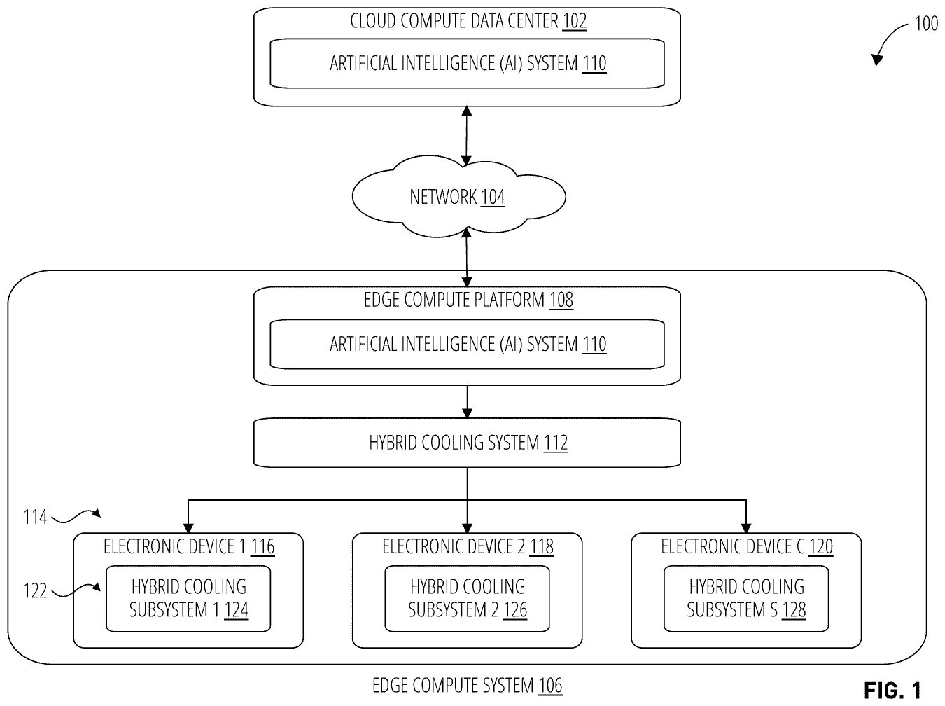

FIG. 1 illustrates a system 100. The system 100 is an example architecture for a system comprising a set of electronic devices suitable for implementing a hybrid cooling system as described herein.

As depicted in FIG. 1, the system 100 comprises a cloud compute data center 102 and an edge compute system 106 communicating through a network 104. The edge compute system 106 comprises an edge compute platform 108 that offers edge services to a set of electronic devices 114, such as electronic device 1 116, electronic device 2 118, and electronic device C 120, where C represents any positive integer.

The cloud compute data center 102 is a facility used by cloud service providers to house computer systems and associated components, such as telecommunications and storage systems, that support the delivery of cloud services. These cloud compute data centers 102 are the backbone of cloud computing, enabling the virtualized and scalable resources offered as services over the internet or dedicated networks. They comprise servers, storage devices, networking equipment, and software that together provide a range of services, including software as a service (SaaS), platform as a service (PaaS), and infrastructure as a service (IaaS). The cloud compute data center 102 allows physical server hardware to run multiple server environments or instances simultaneously, increasing resource utilization and efficiency. The cloud compute data center 102 supports the ability to scale resources up or down as needed, allowing users to dynamically adjust computing power, storage, and bandwidth according to demand. The cloud compute data center 102 increases reliability achieved through redundancy and fault tolerance mechanisms, ensuring high availability and continuity of service even in the event of hardware failure or other issues. The cloud compute data center 102 includes multiple layers of security controls, such as firewalls, intrusion detection systems, and data encryption, to protect data and operations against unauthorized access and cyber threats. The cloud compute data center 102 offers connectivity through high-bandwidth network connections to facilitate quick access to applications, data, and services hosted in the data center from anywhere in the world.

The edge compute system 106 is a distributed computing platform that brings computation and data storage closer to the location where it is needed, to improve response times and save bandwidth. The edge compute system 106 is designed to perform data processing at the edge of the network, near the source of data generation, rather than relying solely on a centralized data processing facility, such as the cloud compute data center 102. This approach is particularly beneficial in scenarios where low latency, high bandwidth, or local data analysis and processing are required. The edge compute system 106 provides close proximity to data sources. Edge computing devices are located close to Internet of Things (IoT) devices, sensors, or other data sources, enabling data to be processed locally instead of being transmitted to a distant server or cloud for analysis. By processing data locally, the edge compute system 106 significantly reduces the latency involved in sending data to and from the cloud, leading to faster decision-making and action based on the analyzed data. Local data processing helps to reduce the amount of data that must be sent over the network, conserving bandwidth and reducing reliance on constant connectivity to centralized cloud services. Edge computing allows for scalable deployment of applications by distributing processing tasks across numerous edge nodes. Processing data locally can help address privacy concerns and comply with data sovereignty regulations, as sensitive information does not have to leave the local site. The edge compute system 106 may include a variety of technologies like the edge compute platform 108, edge servers, IoT devices, and mobile computing devices. They support a wide range of applications, from autonomous vehicles and smart cities to industrial IoT and content delivery networks.

The electronic devices 114 may comprise any type of electronic device suitable for working with the edge compute system 106. The electronic devices 114 often have the capability to either process data locally or to serve as the source or endpoint of data in edge environments. Non-limiting examples of electronic devices 114 include: smartphones and tablets which have powerful processing capabilities and therefore can handle significant computational tasks locally, reducing the need to send data back and forth to the cloud compute data center 102; IoT sensors that gather data from the environment such as temperature sensors, motion detectors, and cameras, can preprocess data before sending it on or make local decisions; industrial controllers used in manufacturing and industrial settings, including programmable logic controllers (PLCs) and industrial PCs that can perform real-time processing at the edge; wearable devices such as smartwatches and health monitors, which can process health and fitness data directly on the device; autonomous vehicles such as cars, drones, and robots that require real-time processing to navigate and interact with their environment efficiently; edge servers which are dedicated hardware located on-premises or near the data source to perform heavier data processing tasks that sensors or smaller devices cannot handle; smart home devices including smart thermostats, lights, and security systems that can process data locally to perform actions without relying on a central server; network gateways which are devices that connect different networks and process data as it passes through, often adding an additional layer of security or data filtering; medical devices such as portable diagnostic devices or patient monitoring equipment that require real-time data processing to provide timely insights; retail Point-of-Sale (POS) systems that can process sales transactions locally to reduce latency and continue operating even in the event of network failures. The suitability of these devices for edge computing depends on their ability to process data locally, their connectivity options, and their capacity to make decisions or take actions based on processed data without always needing to communicate with a central cloud-based system. Advancements in semiconductor technology, artificial intelligence (AI), and machine learning algorithms continue to expand the capabilities and applications of edge computing devices.

One or more of the electronic devices 114 may implement one or more electronic components. Non-limiting examples of electronic components include semiconductor dies, semiconductor devices, semiconductor packages, integrated circuits (IC), XPUs, chips, chipsets, memory units, controllers, network interface cards (NIC), system-on-a-chip (SoC), power supplies, peripheral controllers, bus controllers, circuit boards, printed circuit boards (PCB), motherboards, platform components, and so forth.

The edge compute system 106 includes a hybrid cooling system 112 that implements a combination of different cooling techniques for thermal management to cool the electronic components of the electronic devices 114 on an as-needed or on-demand basis. The hybrid cooling system 112 is responsible for coordinating system thermal management operations for the electronic devices 114. Each of the electronic devices 114 may implement a hybrid cooling subsystem 122 that is responsible for cooling electronic components, such as semiconductor devices, within the electronic devices 114. The hybrid cooling subsystem 122 comprises a combination of different cooling subsystems, such as an air cooling subsystem, a liquid cooling subsystem, a DTC cooling subsystem, an open liquid cooling subsystem, an immersion liquid cooling subsystem, and so forth.

The hybrid cooling system 112 may include a hybrid cooling controller to dynamically control an amount of resources provided to each of the different hybrid cooling subsystems 122, or switch between different hybrid cooling subsystems 122, to precisely control delivery of a defined level of cooling needed by a given electronic device 114. The hybrid cooling controller dynamically adjusts distribution of cooling resources provided by the hybrid cooling system 112 in response to changes in operating conditions for the electronic device 114. The hybrid cooling system 112 is designed for a worst-case scenario and the hybrid cooling controller activates or deactivates the hybrid cooling subsystems 122 on an as-needed or on-demand basis. For example, the hybrid cooling controller may activate the air cooling subsystem of the hybrid cooling subsystem 122 in spring and winter seasons and deactivate the liquid cooling subsystem of hybrid cooling subsystem 122, and it activates the liquid cooling subsystem of the hybrid cooling subsystem 122 in summer and fall seasons and deactivates the air cooling system of the hybrid cooling subsystem 122. In some cases, the hybrid cooling controller partially activates or partially deactivates hybrid cooling subsystems 122 to obtain a balanced amount of cooling from the hybrid cooling subsystems 122 at a local level across an individual electronic device 114. In other cases, the hybrid cooling controller partially activates or partially deactivates hybrid cooling subsystems 122 to obtain a balanced amount of cooling from the hybrid cooling subsystems 122 at a system level across some or all of the electronic devices 114. Further, the hybrid cooling controller can automatically control delivery of cooling within a device chassis of the electronic device 114 to ensure proper cooling of electronic components within the device chassis in accordance with various cooling policies, such as SLOs defined by SLAs associated with the electronic components and/or cooling zones for the electronic components.

In various embodiments, the cloud compute data center 102 and/or the edge compute platform 108 may implement some or all of an AI system 110. The AI system 110 may assist in delivery of various edge services, including control, management, and orchestration of the hybrid cooling system 112 for one or more of the electronic devices 114. In general, the AI system 110 is a computerized system designed to perform tasks that typically require human intelligence. These tasks include understanding natural language, recognizing patterns in data, making decisions based on complex or incomplete information, and learning or improving performance over time based on experience. The AI system 110 is built on a combination of algorithms, software, and, in some cases, specialized hardware that enables them to process and analyze vast amounts of data much faster and more efficiently than human beings can. The AI system 110 may implement various machine learning (ML) algorithms to train ML models that allow the system to learn from and make predictions or decisions based on data, without being explicitly programmed for specific tasks. The AI system 110 may include various machine or computer components (e.g., circuit, processor circuit, memory, network interfaces, compute platforms, input/output (I/O) devices, etc.) for an AI/ML system that are designed to work together to create a pipeline that can take in raw data, process it, train an ML model, evaluate performance of the trained ML model, and deploy the tested ML model as a trained ML model in a production environment, and continuously monitor and maintain it.

The hybrid cooling system 112 may utilize or have access to the AI system 110 to assist in managing cooling operations. The AI system 110 may implement one or more ML algorithms to train one or more ML models. For example, an ML model may receive as input configuration data for the hybrid cooling system 112 and hybrid cooling subsystems 122, and generate one or more metrics for the hybrid cooling system 112 or hybrid cooling subsystems 122 based on the configuration data. The configuration data may comprise a set of system parameters or system rules associated with the hybrid cooling system 112, such as hybrid cooling subsystems 122, electronic components, electronic devices 114, electronic systems, networks, and so forth. In some cases, the system parameters or system rules are defined by a set of policies associated with the hybrid cooling system 112, the hybrid cooling subsystem 122, the electronic device 114, the edge compute system 106, and/or the cloud compute data center 102. Non-limiting examples of policies include cooling policies, orchestration policies, security policies, and so forth. Non-limiting examples of parameters include parameters with values representing an amount of cooling fluid, a type of cooling fluid, a velocity of movement of the cooling fluid, an amount of power for a cooling subsystem, an amount of cooling capacity for a cooling subsystem, and so forth. The ML model may analyze the set of parameters, and it generates a metric for the hybrid cooling system based on the set of parameters. Non-limiting examples of metrics include measurement values, KPIs, operational metrics, system metrics, and so forth. For example, a metric may comprise measurement values representing aging of system components, resource utilization, system energy efficiency, system workloads, operating conditions, environment conditions, ambient conditions, service level objectives against workloads, and so forth. The AI system 110 may modify the various system parameters to the hybrid cooling system 112 to observe effects on the hybrid cooling system 112 through changes to the metrics. Through a series of iterations, the AI system 110 converges on a set of system parameters optimized for the hybrid cooling system. The AI system 110 uses the system parameters to update cooling policies for the hybrid cooling system 112. The ML model, system parameters, and/or cooling policies can be shared with other hybrid cooling systems through a federated system using, for example, P2P communications through a public or private network.

In one embodiment, for example, the AI system 110 implements a ML algorithm to train an ML model using a training dataset generated from historical information associated with thermal management operations of the cloud compute data center 102, the edge compute system 106, and/or the electronic devices 114. The ML model accepts as input sensor data (e.g., ambient temperatures, processing loads, time of day, seasons, etc.) collected from the various sensors of the hybrid cooling system 112, analyzes the sensor data for patterns, and generates predictions for managing cooling of one or more of the electronic devices 114. The ML model may comprise, for example, an artificial neural network (ANN), such as a long short-term memory (LSTM) neural network. When the ML model predicts that an electronic component needs thermal management, the ML model sends a control directive to the hybrid cooling system 112 to activate cooling of the electronic component.

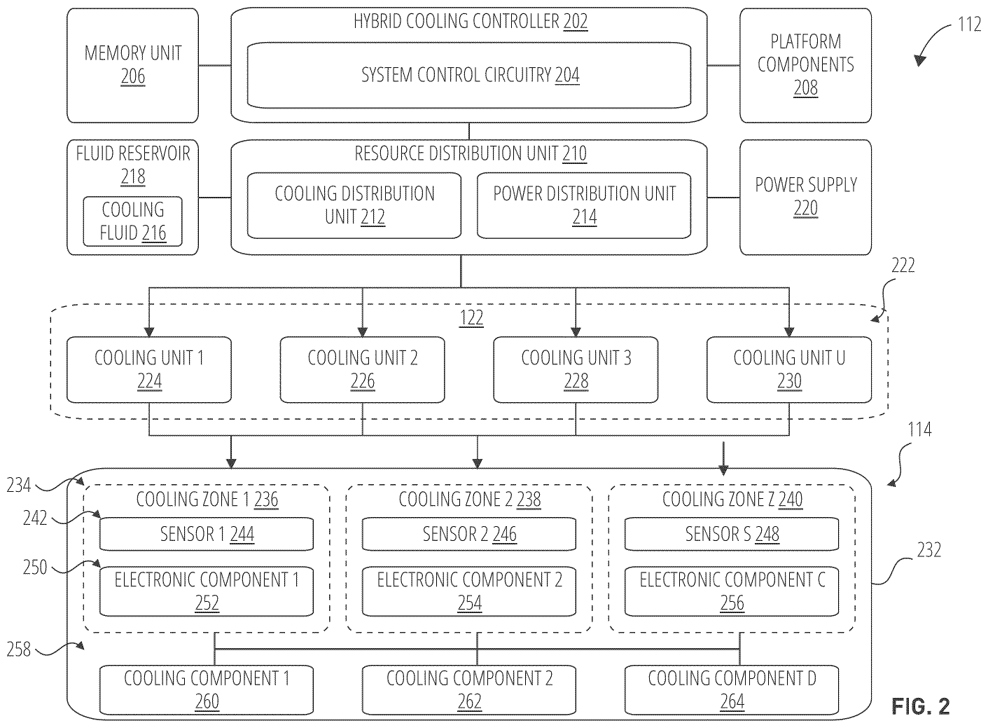

FIG. 2 illustrates an example of an architecture or framework for a hybrid cooling system 112 for the edge compute system 106.

As depicted in FIG. 2, the cooling system 200 comprises a hybrid cooling controller 202 to coordinate thermal management operations for the hybrid cooling system 112. The hybrid cooling controller 202 comprises system control circuitry 204. The system control circuitry 204 is circuitry to execute instructions, such as executable code of a binary, to control operations for the hybrid cooling system 112. The system control circuitry 204 may access the instructions from a memory unit 206 for execution by the system control circuitry 204. Additionally, or alternatively, the system control circuitry 204 may be implemented as hardware, such as an application specific integrated circuit (ASIC) or a field-programmable gate array (FPGA). Embodiments are not limited in this context.

The hybrid cooling system 112 comprises a resource distribution unit 210. The resource distribution unit 210 controls distribution of resources for the hybrid cooling system 112. Specifically, the resource distribution unit 210 controls distribution of resources to one or more cooling units 222 implemented for a hybrid cooling subsystem 122 of an electronic device 114. The cooling units 222 may comprise a cooling unit 1 224, a cooling unit 2 226, a cooling unit 3 228, and a cooling unit U 230, where U represents any positive integer. A cooling unit 222 may control a cooling component 258 for an electronic component 250. A cooling component 258 may comprise part of a larger cooling system that may implement a particular cooling technique or solution suitable for the electronic component 250. Non-limiting examples of a cooling component 258 include fans and heat sinks for an air cooling system, fluid pipes and valves for a liquid cooling system, a sprayer or pumps for a DTC cooling system, an open tank for an open liquid cooling system, a closed tank for an immersion liquid cooling system, and so forth.

The cooling components 258 may comprise internal cooling components designed to implement any number of cooling technologies for thermal management or cooling of the electronic components 250. Cooling technologies for electronic components 250 within the electronic device 114 encompass a variety of methods designed to dissipate heat and maintain optimal operational temperatures. Non-limiting examples of these technologies include air cooling, liquid cooling, heat pipes, phase change material (PCM) cooling, thermoelectric cooling, and immersion cooling. For instance, a cooling component 258 may implement air cooling utilizing fans, blowers, or refrigerants to circulate cold air across the electronic components 250 or heat sinks/cold plates attached to electronic components 250, facilitating heat dissipation. In another example, a cooling component 258 may be a cooling head or cooling drop for liquid cooling systems using a coolant liquid which circulates through a loop, absorbing heat from the components before being cooled down in a radiator. In yet another example, a cooling component 258 may comprise heat pipes for conducting heat away from the electronic components 250 to a cooler area where it can be dissipated more efficiently, such as an external cooling component for the electronic device 114. In another example, a cooling component 258 may implement a heat sink or a cold plate to physically touch an electronic component 250. In yet another example, a cooling component 258 may comprise a vacuum pump to suck heated air away from an electronic component 250. In another example, a cooling component 258 may use a form of PCM cooling that leverages materials that absorb heat as they change from solid to liquid, effectively regulating component temperatures. In still another example, a cooling component 258 may implement thermoelectric cooling that employs the Peltier effect to create a heat flux between the junction of two different types of materials, allowing for cooling below ambient temperature. In another example, a cooling component 258 may implement a form of immersion cooling that involves spraying liquid coolant on an electronic component 250, or submerging some or all of an electronic component 250 in a non-conductive liquid that dissipates heat effectively. Embodiments are not limited to these examples.

Each of these cooling technologies offer distinct advantages and are selected based on specific requirements such as cooling capacity, energy efficiency, space constraints, and the thermal management needs of the electronic device. Air and liquid cooling systems are widely used for their balance of efficiency and cost-effectiveness, suitable for a vast range of electronic devices from consumer electronics to server farms. Heat pipes and PCM cooling are noted for their passive cooling capabilities, making them ideal for applications where minimal maintenance is desired. Thermoelectric coolers, while less commonly used due to their higher energy consumption, offer precise temperature control. Immersion cooling, considered an advanced solution, is gaining popularity in data centers and high-performance computing applications due to its superior cooling efficiency and potential for space savings. Ultimately, selection of a particular cooling technology is dependent on such design factors as reliability, performance requirements, and longevity of the cooling components 258 and/or electronic components 250 in various applications.

Each of the cooling components 258 may comprise a set of structures that is arranged to perform thermal management and deliver cooling to any of the cooling zones 234 and/or electronic components 250. Similarly, the cooling units 222 for the hybrid cooling subsystem 122 may control any of the cooling components 258 to cause the cooling components 258 to perform thermal management and deliver cooling to any of the cooling zones 234 and/or electronic components 250. For example, the cooling unit 1 224 may activate, deactivate, or control an amount of cooling delivered by the cooling component 1 260, the cooling component 2 262, and/or the cooling component D 264, the cooling unit 2 226 may also activate, deactivate, or control an amount of cooling delivered by the 260, the cooling component 2 262, and/or the cooling component D 264, and so forth. Further, any of the cooling units 222 may activate, deactivate, or control an amount of cooling delivered by any of the cooling components 258 to any of the cooling zones 234 and/or electronic components 250. For example, the cooling unit 3 228 may activate, deactivate, or control an amount of cooling delivered by the cooling component 2 262 to the cooling zone 1 236, the cooling zone 2 238, and/or the cooling zone Z 240, the cooling unit U 230 may activate, deactivate, or control an amount of cooling delivered by the cooling component D 264 to the electronic component 1 252, the electronic component 2 254, and/or the electronic component C 256, and so forth.

The hybrid cooling system 112 may implement and control multiple different types of cooling systems. In one embodiment, for example, the hybrid cooling system 112 implements at least two different types of cooling systems and associated cooling components 258, such as an air cooling system and a liquid cooling system, for example. The hybrid cooling system 112 may implement any number of cooling systems as suitable for a given implementation depending on a set of physical, electrical, and thermal design constraints for an electronic device 114, an electronic component 250 for an electronic device 114, a device chassis 232, a system chassis (e.g., a server rack), an edge compute system 106, and/or a cloud compute data center 102.

The hybrid cooling system 112 includes a resource distribution unit 210. The 210 is responsible for distribution of system resources to the cooling components 258 for the different cooling systems. For example, when the hybrid cooling system 112 implements a liquid cooling system, the resource distribution unit 210 comprises a cooling distribution unit 212 to manage distribution of cooling fluid 216 from a fluid reservoir 218 to cooling units 222 and cooling components 258, such as open or closed immersion tanks, for example. The resource distribution unit 210 further comprises a power distribution unit 214 to manage distribution of power from the power supply 220 to the cooling units 222 and/or the electronic components 250. When the hybrid cooling system 112 implements an air cooling system, the power distribution unit 214 may increase or decrease an amount of power to cooling components 258, such as fans or refrigerant units, for example.

The fluid reservoir 218 is a component that holds the cooling fluid 216 or coolant. The primary purpose of the fluid reservoir 218 is to maintain an adequate volume of cooling fluid 216 within the hybrid cooling system 112, ensuring that there is always enough cooling fluid 216 to circulate and efficiently transfer heat away from the components being cooled, such as the electronic components 250. The fluid reservoir 218 acts as a storage tank for the cooling fluid 216, providing a buffer of cooling fluid 216 that can be drawn into the cooling loop as needed. This is particularly important during system start-up or when any part of the system needs additional coolant due to evaporation or leakage. The fluid reservoir 218 also provides a convenient point for adding or replacing coolant in the system. It allows for easy access to the fluid for maintenance purposes, such as flushing the system or replenishing coolant levels. The fluid reservoir 218 helps in removing air bubbles from the cooling fluid 216. Air bubbles can significantly reduce the efficiency of heat transfer and can cause noise in the system. The design of the fluid reservoir 218 allows air bubbles to rise out of the circulating cooling fluid 216 and collect at the top, away from the main flow, where they can be vented outside the system. Having a fluid reservoir 218 can also assist in temperature stabilization. The volume of cooling fluid 216 in the fluid reservoir 218 provides a thermal buffer that can absorb and dissipate heat, helping to moderate temperature fluctuations within the system. It can also serve to relieve pressure within the cooling system. As the cooling fluid 216 heats up and expands, the fluid reservoir 218 accommodates the increased volume, preventing excessive pressure build-up that could lead to leaks or damage to system components. The fluid reservoir 218 can come in various sizes and designs, ranging from simple closed tanks to sophisticated pressurized containers, depending on system requirements and the specific applications.

The fluid reservoir 218 holds or stores cooling fluid 216. A cooling fluid 216 may transfer heat from the electronic components 250 to a cooling component 258, such as a heat exchanger which dissipates heat from the heated liquid into the ambient, or another separate liquid cooling component or system. Examples of cooling fluids 216 include engineered fluids such as 3M™ Novec™ and Fluorinert™, synthetic oils, and specially formulated dielectric fluids. In one embodiment, for example, the cooling fluid 216 flowing through the liquid cooling path is a non-electric-conductive, non-ionic, and non-reactive liquid (e.g., a fluorinated liquid). In another embodiment, the fluid may be water when the electronic component 250 (e.g., a semiconductor die) is surrounded with an insulated material. In some embodiments, the cooling fluid 216 may be a fluorinated liquid type and/or a freon liquid type. Examples of a fluorinated liquid type may include without limitation FC-3283, FC-40, FC-43, FC-72, FC-75, FC-78, and FC-88. In one embodiment, for example, the freon liquid type may include freon-C-51-12, freon-E5, or freon-TF. Embodiments are not limited to these examples.

Two parameters of cooling fluid 216 to consider when choosing a cooling fluid 216 for use in a particular cooling implementation are its flammability and global warming potential (GWP) number, with a lower GWP number indicating that a material contributes less to global warming. Some synthetic single-phase cooling liquids (e.g., Novec fluids) have good thermal performance but also have a high GWPs. As there are worldwide efforts to phase out the use of greenhouse gases, such as hydrofluorocarbons, there is interest in using non-GWP or low-GWP materials (e.g., materials having a GWP<1) where possible. The liquid cooling technologies disclosed herein can provide for the liquid cooling of electronic devices and systems comprising high-performance IC components using non-flammable and/or non-GWP or low-GWP fluids. The use of such technologies can aid large cloud service providers (CSPs), high-performance computing (HPC) system vendors, and other entities that may begin to increasingly rely on liquid cooling in data centers to meet defined environmental sustainability (e.g., carbon-neutral, carbon-negative) goals.

As previously discussed, the electronic device 114 is divided into one or more cooling zones 234, such as cooling zone 1 236, cooling zone 2 238, and cooling zone Z 240, where Z represents any positive integer. A cooling zone is a defined area within the device chassis 232. The defined area may be a 2D area or a 3D area within the device chassis 232. Each cooling zone 234 includes one or more electronic components 250. For example, the cooling zone 1 236 includes an electronic component 1 252, the cooling zone 2 238 includes an electronic component 2 254, and the cooling zone Z 240 includes an electronic component C 256, where C represents any positive integer. Further, each cooling zone 234 includes one or more sensors 242, such as a sensor 1 244, a sensor 2 246, and a sensor S 248, where S represents any positive integer. One or more cooling units 222 control cooling operations for one or more cooling components 258 that are positioned within a defined distance from the electronic components 250. The defined distance is a configurable parameter based on a type of cooling technique implemented for each of the cooling components 258. In some cases, the defined distance is zero which means the cooling component 258 makes actual physical contact with the electronic component 250.

In one embodiment, for example, the system control circuitry 204 receives and decodes sensor data (or telemetry data) from a sensor 242 of a cooling zone 234 or an electronic component 250 of the electronic device 114. The sensors 242 may monitor various properties and attributes of the hybrid cooling system 112 to ensure efficient operation, safety, and performance monitoring. For example, the sensors 242 may include temperature sensors designed to measure the temperature of the liquid coolant and components being cooled, such as the electronic components 250. Common types of temperature sensors include thermocouples, thermistors, and resistance temperature detectors (RTDs). The sensors 242 may include flow sensors designed to measure a flow rate of the cooling fluid 216 in the system, ensuring it is circulating properly. Examples include turbine flow sensors, ultrasonic flow sensors, and paddlewheel sensors. The sensors 242 may include pressure sensors designed to measure the pressure of the cooling fluid 216 within the hybrid cooling system 112. This is important for detecting leaks, blockages, or pump failures. Common types include piezoelectric pressure sensors and strain gauge pressure sensors. The sensors 242 may include level sensors designed to detect a coolant level within the fluid reservoir 218, ensuring the system has enough cooling fluid 216 to function properly. Types include capacitive level sensors, ultrasonic level sensors, and float level sensors. The sensors 242 may include pH sensors designed to monitor an acidity or alkalinity of the cooling fluid 216 to prevent corrosion-related damage. The sensors 242 may include conductivity sensors designed to measure the electrical conductivity of the cooling fluid 216. This can be important for detecting contamination or the concentration of additives in the cooling fluid 216. The sensors 242 may include temperature difference sensors designed to measure a temperature difference across the cooling system to assess its efficiency. Each of the sensors 242 plays a role in monitoring and controlling a liquid cooling system, contributing to its effectiveness and longevity. Embodiments are not limited to these examples.

The system control circuitry 204 analyzes the sensor data (or telemetry data), and it generates one or more control directives and sends them to the resource distribution unit 210 to distribute system resources, such as cooling fluid 216 from the fluid reservoir 218 or power from the power supply 220, through the cooling units 222 of the hybrid cooling subsystem 122 to the cooling components 258 for the electronic components 250 of the electronic device 114. Further, the system control circuitry 204 generates one or more control directives and sends them to the cooling units 222 to adjust an amount of cooling delivered to an electronic component 250 in a cooling zone 234 by the cooling components 258.

In some embodiments, the system control circuitry 204 may access configuration data for a cooling zone 234 where the electronic component 250 is located to assist in cooling decisions. The configuration data may include, for example, a volumetric area for the cooling zone 234, an SLO defined by an SLA defining an operating target for the cooling zone 234, a priority level associated with the cooling zone 234, reservation data for the cooling zone 234, and other parameters. The configuration data may also include a set of system parameters, system rules, operating rules, or operating conditions to determine when and what type of thermal management to deliver to the cooling zone 234 or the electronic component 250. For example, a cooling component 258 may be designed with a maximum cooling capacity for a worst-case scenario, such as an extreme temperature in a season or locality for the electronic device 114 or the entire edge compute system 106.

The configuration data may comprise a set of operating rules defining when to utilize some or all of the maximum cooling capacity. For example, assume an electronic device 114 is located in a geographic area with changing seasons, such as spring, summer, winter, and fall. The configuration data may include a set of operating rules indicating a cooling component 258 is to deliver X amount of cooling for a Y percentage of time to an electronic device 114 or cooling zone 234, such as winter-time high-end cooling is needed 5% of the time, spring-time high-end cooling is needed 20% of the time, and summer-time high-end cooling is needed 60% of the time. In another example, the configuration data may include a set of operating rules indicating a cooling unit 1 224 is to cause a cooling component cooling component 1 260 to deliver X amount of cooling for a Y percentage of time to an electronic device 114 or cooling zone 234, and a cooling unit 2 226 causes a cooling component 2 262 to deliver R amount of cooling for a S percentage of time to the electronic device 114 or the cooling zone 234. For example, assume the cooling unit 1 224 controls a cooling component 1 260 implemented as an air cooling unit and the cooling unit 2 226 controls a cooling component 2 262 implemented as a liquid cooling unit. The hybrid cooling system 112 may activate the cooling unit 1 224 to cause the cooling component 1 260 to perform air cooling during night-time hours when ambient conditions are cooler and the cooling unit 2 226 to cause the cooling component 2 262 to perform liquid cooling during day-time hours when ambient conditions are hotter. In yet another example, the configuration data may include a set of operating rules indicating a cooling unit 1 224 is to cause a cooling component 2 262 to deliver X amount of cooling for a Y percentage of time to an electronic device 114 or cooling zone 234 when an ambient temperature is above R degrees or an electronic component 250 approaches S percentage of its dynamic thermal range (DTR) limit. In still another example, the configuration data may include a set of operating rules indicating a cooling unit 1 224 is to cause the cooling component 2 262 implemented as a liquid cooling unit that is capable of using three different types of cooling fluid 216, such as an A type, B type, and C type of cooling fluid 216. The system control circuitry 204 may instruct the resource distribution unit 210 to deliver the different types of cooling fluid 216 on a seasonal basis (e.g., summer versus winter), a time basis (e.g., night versus day), a cooling capacity basis (e.g., high-end cooling versus low-end cooling), a type of electronic device 114 (e.g., general server versus AI server), a type of electronic component 250 (e.g., an XPU versus a memory unit), and other factors. Any number of operating rules or operating conditions may be defined for the hybrid cooling system 112. Embodiments are not limited to these examples.

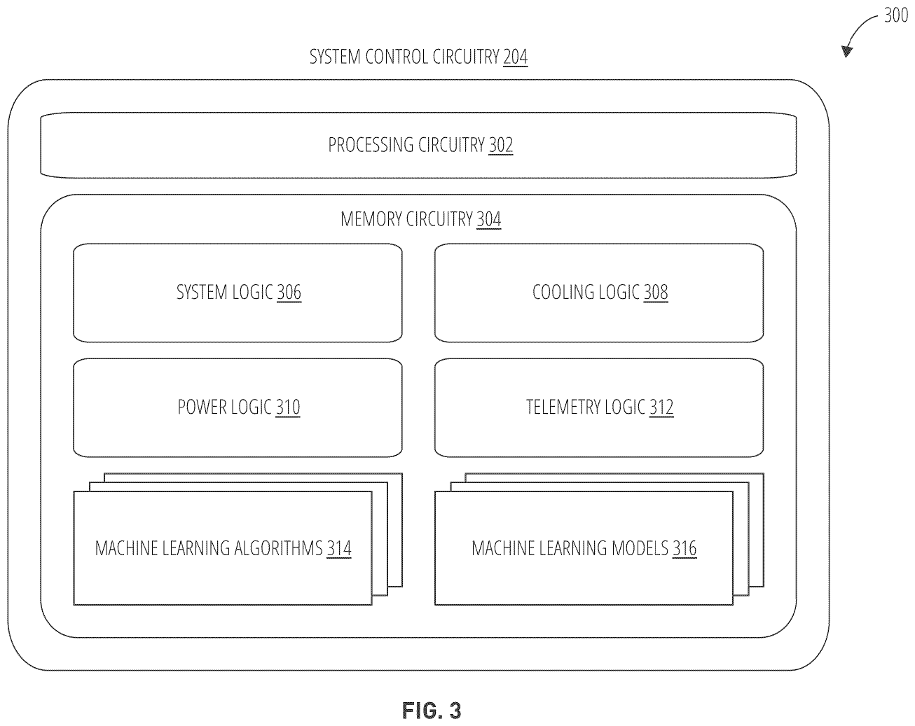

FIG. 3 illustrates an apparatus 300. The apparatus 300 comprises an example implementation for the system control circuitry 204.

As depicted in FIG. 3, the system control circuitry 204 of the apparatus 300 comprises processing circuitry 302 and memory circuitry 304. The memory circuitry 304 comprises a set of executable instructions for various logic blocks, such as system logic 306, cooling logic 308, power logic 310, and telemetry logic 312. The memory circuitry 304 also stores executable instructions for one or more ML algorithm 314 to train one or more ML model 316.

The system logic 306 controls or manages overall system operations for the hybrid cooling system 112. This includes operations such as generating configuration data for the cooling zones 234 of the electronic device 114, decoding sensor data from the sensors 242, analyzing sensor data based on the configuration data, predicting thermal limits for the electronic component 250, and so forth. The system logic 306 also generates control directives to control cooling operations and power operations for the resource distribution unit 210, the cooling units 222, and the electronic components 250. For example, the system logic 306 generates control directives to the cooling units 222 to apply precision cooling to the electronic components 250 within the cooling zones 234.

The cooling logic 308 controls or manages cooling operations for the cooling distribution unit 212 of the resource distribution unit 210. The cooling logic 308 receives the control directives from the system logic 306, and it controls distribution of the cooling fluid 216 from the fluid reservoir 218 to the cooling units 222. For example, the cooling logic 308 may increase an amount of cooling fluid 216 delivered to the cooling units 222, decrease an amount of cooling fluid 216 delivered to the cooling units 222, modify a type of cooling fluid 216 used by the cooling units 222, drain some or all of the cooling fluid 216 from the cooling units 222, and so forth.

The power logic 310 controls or manages power operations for the power distribution unit 214 of the resource distribution unit 210. The power logic 310 receives the control directive from the system logic 306, and it controls distribution of power from the power supply 220 to the cooling units 222 and/or the electronic components 250. For example, the power logic 310 may increase an amount of power delivered to the cooling unit 222 to increase cooling operations, decrease an amount of power delivered to the cooling unit 222 to decrease cooling operations, increase on amount of power delivered to the electronic component 250 to increase compute operations for the electronic component 250, decrease an amount of power delivered to the electronic component 250 to decrease compute operations for the electronic component 250, turn on or off the cooling unit 222, turn on or off the cooling component 258, turn on or off the electronic component 250, and so forth.

The telemetry logic 312 controls or manages operations for the sensors 242 disposed within the cooling zones 234. The telemetry logic 312 manages system telemetry data for the electronic device 114, which includes the automated collection, transmission, and analysis of sensor data regarding the performance, health, and behavior of the computing devices, software, interconnects, and networks that constitute the electronic device 114. This data is used for monitoring, managing, and optimizing system performance and ensuring the reliability and security of device operations.

The system control circuitry 204 may implement a set of AI or ML techniques to assist in managing the hybrid cooling system 112. For example, the system control circuitry 204 may implement one or more ML algorithms 314 to train one or more ML models 316 to configure or re-configure the cooling zones 234 and the cooling units 222 for the cooling zone 234, generate thermal limits for the electronic components 250, predict when the electronic components 250 are approaching thermal limits, calculating cooling capacity of the cooling units 222, calculating cooling requirements for the electronic components 250, and other downstream tasks.

The system control circuitry 204 may implement one or more ML algorithms 314. For example, the system control circuitry 204 may implement one or more lambda functions. A lambda function is a relatively small, anonymous function defined with the lambda keyword in programming languages like Python. It is often used in machine learning code for conciseness and flexibility, especially in data manipulation and feature engineering phases. A lambda function in Python allows the function to take any number of arguments but comprises only one expression, the result of which is returned by the function. In machine learning, Lambda functions are frequently used in data preprocessing steps to apply transformations to data elements. For example, a lambda function may convert temperatures from Celsius to Fahrenheit across a dataset. When creating or modifying features in a dataset, lambda functions can apply quick, inline calculations or transformations without the need for defining a separate, named function. Lambda functions are often used with map( ) filter( ) and reduce( ) functions to apply operations on lists or columns in a Data Frame. For instance, applying a lambda function to scale a numerical feature in a pandas Data Frame column.

The system control circuitry 204 may implement the lambda functions to pre-process data from various logic or components of the electronic device 114 or multiple electronic devices 114 using the hybrid cooling system 112. The output of the lambda functions is a training dataset suitable for training an ML model, such as the ML model 316. In some cases, the system control circuitry 204 may employ a set of filters to filter the output from the lambda functions to limit the output to a dataset suitable for inclusion in the training dataset, and outputs the training dataset for use by the system control circuitry 204. For example, the system control circuitry 204 of the electronic device 114 may output the training dataset to a server device of a cloud compute data center or an edge system to train the ML model 316.

A cloud compute data center 102 comprises a set of servers, such as a server pool or server farm. The server device executes an ML algorithm 314 to train an ML model 316 using the training dataset. Once the ML model 316 is trained, the server device uses the trained ML model and sends instructions to the hybrid cooling system 112, or sends the trained ML model to the hybrid cooling system 112, for deployment as prediction logic to perform inferencing operations to support the cooling logic 308.

The ML model 316 is a mathematical construct used to predict outcomes based on a set of input data. The ML model 316 is trained using large volumes of training data from the training dataset, and it can recognize patterns and trends in the training data to make accurate predictions. The ML model 316 is derived from an ML algorithm 314. The training dataset is fed into the ML algorithm 314 which trains the ML model 316 to “learn” a function that produces mappings between a set of inputs and a set of outputs with a reasonably high accuracy. Given a sufficiently large enough set of inputs and outputs, the ML algorithm 314 finds the function for a given task. This function may even be able to produce the correct output for input that it has not seen during training. A data scientist prepares the mappings, selects and tunes the ML algorithm 314, and evaluates the resulting model performance. Once the ML model 316 is sufficiently accurate on test data, it can be deployed for production use.

The ML algorithm 314 may comprise any ML algorithm suitable for a given AI task. Examples of ML algorithms may include supervised algorithms, unsupervised algorithms, semi-supervised algorithms, or reinforcement learning algorithms.

A supervised algorithm is a type of machine learning algorithm that uses labeled data to train a machine learning model. In supervised learning, the machine learning algorithm is given a set of input data and corresponding output data, which are used to train the model to make predictions or classifications. The input data is also known as the features, and the output data is known as the target or label. The goal of a supervised algorithm is to learn the relationship between the input features and the target labels, so that it can make accurate predictions or classifications for new, unseen data. Examples of supervised learning algorithms include: (1) linear regression which is a regression algorithm used to predict continuous numeric values, such as stock prices or temperature; (2) logistic regression which is a classification algorithm used to predict binary outcomes, such as whether a customer will purchase or not purchase a product; (3) decision tree which is a classification algorithm used to predict categorical outcomes by creating a decision tree based on the input features; or (4) random forest which is an ensemble algorithm that combines multiple decision trees to make more accurate predictions.

An unsupervised algorithm is a type of machine learning algorithm that is used to find patterns and relationships in a dataset without the need for labeled data. Unlike supervised learning, where the algorithm is provided with labeled training data and learns to make predictions based on that data, unsupervised learning works with unlabeled data and seeks to identify underlying structures or patterns. Unsupervised learning algorithms use a variety of techniques to discover patterns in the data, such as clustering, anomaly detection, and dimensionality reduction. Clustering algorithms group similar data points together, while anomaly detection algorithms identify unusual or unexpected data points. Dimensionality reduction algorithms are used to reduce the number of features in a dataset, making it easier to analyze and visualize. Unsupervised learning has many applications, such as in data mining, pattern recognition, and recommendation systems. It is particularly useful for tasks where labeled data is scarce or difficult to obtain, and where the goal is to gain insights and understanding from the data itself rather than to make predictions based on it.

Semi-supervised learning is a type of machine learning algorithm that combines both labeled and unlabeled data to improve the accuracy of predictions or classifications. In this approach, the algorithm is trained on a small amount of labeled data and a much larger amount of unlabeled data. The main idea behind semi-supervised learning is that labeled data is often scarce and expensive to obtain, whereas unlabeled data is abundant and easy to collect. By leveraging both types of data, semi-supervised learning can achieve higher accuracy and better generalization than either supervised or unsupervised learning alone. In semi-supervised learning, the algorithm first uses the labeled data to learn the underlying structure of the problem. It then uses this knowledge to identify patterns and relationships in the unlabeled data, and to make predictions or classifications based on these patterns. Semi-supervised learning has many applications, such as in speech recognition, natural language processing, and computer vision. It is particularly useful for tasks where labeled data is expensive or time-consuming to obtain, and where the goal is to improve the accuracy of predictions or classifications by leveraging large amounts of unlabeled data.

Reinforcement Learning is a type of machine learning paradigm that is primarily concerned with how agents ought to take actions in an environment to maximize the cumulative reward. Unlike supervised learning where models are trained on a dataset containing inputs paired with correct outputs, reinforcement learning involves an agent that interacts with its environment to learn the best actions to take in different states through trial and error. In a reinforcement learning system, an agent is the learner or decision-maker that takes actions and the environment is the world through which the agent moves and learns from the consequences of its actions. State is a representation of the current situation of the agent in the environment. The state space can be the set of all possible situations the agent can face. Actions are all the possible moves that the agent can make. The set of actions available can depend on the state. 5. Reward is signal from the environment in response to the agent's action, indicating the value of the action taken. The agent's objective is to maximize the cumulative reward over time. Policy sets a strategy used by the agent, mapping states to actions, that dictates the action an agent takes in a given state. A value function estimates the expected cumulative reward of taking an action in a state, following a particular policy. It helps in evaluating the goodness of each state and deciding the next action. A model is a representation of the environment that can predict how the environment will respond to an agent's actions. In model-based reinforcement learning, the agent uses it to plan by considering future possibilities, while in model-free reinforcement learning, the agent learns exclusively from trial and error. The learning process in RL involves exploration (trying out new actions to discover their effects) and exploitation (using known information to make the best decision). Reinforcement learning algorithms are categorized into various approaches, such as value-based methods, policy-based methods, and actor-critic methods. Value-based methods focus on learning the value function, with Q-Learning being a prominent example. Policy-based methods involve directly learning the policy function that maps states to the optimal actions without requiring a value function. Actor-critic methods combine value-based and policy-based methods by using two models, with one to determine the action to take (actor) and another to evaluate the action (critic). Reinforcement learning is used in a wide range of applications, from game playing and robotics to recommendation systems and autonomous vehicles, where the challenge is to make a sequence of decisions that will lead to an optimal outcome.

The ML algorithm 314 is implemented using various types of ML algorithms including supervised algorithms, unsupervised algorithms, semi-supervised algorithms, reinforcement learning algorithms, or a combination thereof. A few examples of ML algorithms include support vector machine (SVM), random forests, naive Bayes, K-means clustering, neural networks, and so forth. A SVM is an algorithm that can be used for both classification and regression problems. It works by finding an optimal hyperplane that maximizes the margin between the two classes. Random forests is a type of decision tree algorithm that is used to make predictions based on a set of randomly selected features. Naive Bayes is a probabilistic classifier that makes predictions based on the probability of certain events occurring. K-Means Clustering is an unsupervised learning algorithm that groups data points into clusters. Neural networks is a type of machine learning algorithm that is designed to mimic the behavior of neurons in the human brain. Other examples of ML algorithms include a support vector machine (SVM) algorithm, a random forest algorithm, a naive Bayes algorithm, a K-means clustering algorithm, a neural network algorithm, an artificial neural network (ANN) algorithm, a convolutional neural network (CNN) algorithm, a recurrent neural network (RNN) algorithm, a long short-term memory (LSTM) algorithm, a deep learning algorithm, a decision tree learning algorithm, a regression analysis algorithm, a Bayesian network algorithm, a genetic algorithm, a federated learning algorithm, a distributed artificial intelligence algorithm, and so forth. Embodiments are not limited in this context.

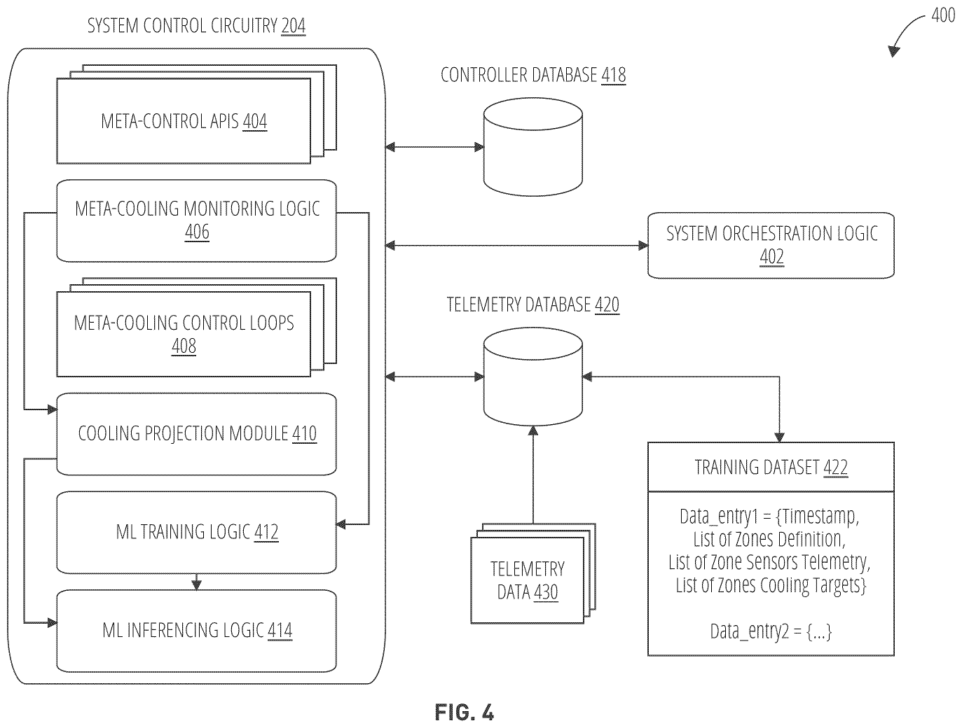

FIG. 4 illustrates a logic diagram 400. The logic diagram 400 comprises a more detailed architecture for the system control circuitry 204 of the hybrid cooling controller 202 to control or manage various parts, components, modules and/or devices of the hybrid cooling system 112.

As depicted in FIG. 4, the logic diagram 400 illustrates a system orchestration logic 402 and the system control circuitry 204 for the hybrid cooling controller 202. The system control circuitry 204 comprises a set of meta-control APIs 404, a meta-cooling monitoring logic 406, a set of meta-cooling control loops 408, a cooling projection module 410, an ML training logic 412, and an ML inferencing logic 414.

The system orchestration logic 402 accesses and utilizes the various components of the system control circuitry 204 to control overall thermal operations for a system, such as the edge compute system 106. In one embodiment, for example, the system orchestration logic 402 is implemented by the edge compute platform 108 of the edge compute system 106. In one embodiment, for example, the system orchestration logic 402 is implemented by a server of the cloud compute data center 102. The system orchestration logic 402 refers to software mechanisms and algorithms designed to manage, coordinate, and optimize the various components and services within an edge computing architecture, such as the edge compute system 106, in accordance with one or more orchestration policies. The system orchestration logic 402 handles the complex, distributed nature of edge computing networks, where resources and workloads are dispersed across numerous edge locations closer to data sources or end-users, rather than centralized in a cloud or data center. For example, the system orchestration logic 402 performs resource allocation by dynamically allocating and deallocating resources such as computing power, memory, and storage across the edge compute system 106 to meet the demands of different workloads efficiently. This also involves monitoring resource utilization to prevent bottlenecks and ensure optimal performance. The system orchestration logic 402 automates the deployment of applications and services to various edge nodes based on predefined policies or real-time requirements. This includes scaling services up or down in response to changing workloads or network conditions to maintain performance levels and service availability. The system orchestration logic 402 configures network settings and managing connectivity across the edge computing infrastructure to ensure data is routed efficiently, securely, and with minimal latency. This can involve optimizing data paths, managing bandwidth, and ensuring secure connections between edge nodes and central servers or other resources. The system orchestration logic 402 enforces security policies and mechanisms to protect data and applications across the edge network. This includes managing access controls, encrypting data in transit and at rest, and monitoring for threats or vulnerabilities. The system orchestration logic 402 coordinates the processing and analysis of data collected at the edge, including decisions on what data should be processed locally versus sent back to centralized data centers for further analysis. This helps to reduce latency and network congestion while enabling real-time insights and actions. The system orchestration logic 402 performs fault tolerance and recovery operations for ensuring the reliability of the edge compute system 106 by detecting failures, automatically rerouting workloads, or restarting services as needed to minimize downtime and maintain continuous operation. The system orchestration logic 402 performs interoperability and integration functions to facilitate communication and data exchange between disparate devices, systems, and platforms within the edge ecosystem, ensuring seamless integration and cooperation among different components. By providing centralized control and automation over these aspects, the system orchestration logic 402 enables efficient, secure, and responsive operations across the edge compute system 106, catering to the unique requirements of deploying and managing workloads at a network edge.

The system control circuitry 204 of the hybrid cooling controller 202 comprises a set of meta-control APIs 404. A meta-control API is a software interface that provides a high-level control mechanism over the hybrid cooling system 112. For example, the system orchestration logic 402 may uses the meta-control APIs 404 to control operations of the hybrid cooling system 112 in accordance with orchestration policies of the edge compute system 106. The meta-control APIs 404 enable dynamic management and adjustment of cooling methodologies based on various operational parameters such as temperature, workload, and energy efficiency requirements. The meta-control APIs 404 facilitate seamless transitions between different cooling components 258, such as an air cooling component of an air cooling system and a liquid cooling component of a liquid cooling system. The meta-control APIs 404 optimize performance by leveraging the strengths of each cooling method, and ensures optimal thermal management across different operational states of an electronic device 114, a set of electronic devices 114, or a system being cooled such as edge compute system 106. They allow for sophisticated algorithms to automatically determine the most effective cooling strategy in real-time, thereby enhancing the overall efficiency and effectiveness of the hybrid cooling system 112.

The system control circuitry 204 of the hybrid cooling controller 202 comprises a meta-cooling monitoring logic 406. Meta-cooling monitoring logic 406 refers to the advanced software logic or algorithms designed to continuously analyze, assess, and respond to the cooling requirements of the edge compute system 106 that utilizes the hybrid cooling system 112. The meta-cooling monitoring logic 406 ensures the hybrid cooling system 112 operates efficiently and effectively under varying operational conditions. By gathering data from sensors 242 (e.g., temperature sensors, flow rate sensors) embedded in the cooling zones 234 within the device chassis 232 of the electronic device 114, the meta-cooling monitoring logic 406 can make informed decisions about when to activate or deactivate each cooling unit 222 and cooling components 258, how to adjust parameters such as fan speed or coolant flow rate, and identify an optimal cooling strategy to maintain the system within desired thermal thresholds. Additionally, the meta-cooling monitoring logic 406 can predict thermal trends and preemptively adjust cooling strategies before temperatures reach critical levels, enhancing system reliability and performance.

The system control circuitry 204 of the hybrid cooling controller 202 comprises a set of meta-cooling control loops 408. The meta-cooling control loops 408 represent a structured, algorithmic framework designed to regulate the operation of hybrid cooling system 112 that integrates different types of cooling components 258. The meta-cooling control loops 408 operate on telemetry data 430 (e.g., sensor data) continuously collected from the sensors 242, such as temperature, humidity, and airflow sensors. The meta-cooling control loops 408 use this data to make real-time decisions on the most efficient cooling strategy to employ at any given moment. For example, the meta-cooling control loops 408 involve sensing and collecting real-time data related to system performance and environmental conditions affecting cooling efficiency. This includes temperatures at various points, coolant flow rates, air velocity, and external temperatures. The collected data is then processed by control loop logic, which often involves sophisticated algorithms or ML models capable of analyzing trends, predicting future states, and making decisions on how to adjust cooling parameters. This operation determines a type of cooling, such as air cooling, liquid cooling, or a combination of both, is optimal for current conditions. Based on the decision-making process, the meta-cooling control loops 408 send commands to the cooling components 258, such as actuators, pumps, valves, and fans, adjusting their operation to implement the chosen cooling strategy. For example, it may increase the fan speed for air cooling, adjust a flow rate of the cooling fluid 216 for liquid cooling, or engage both systems to varying degrees. The outcome of these adjustments is monitored to provide feedback into the meta-cooling control loops 408, enabling them to continuously refine their decisions and adapt to changing conditions. This closed-loop operation ensures optimal thermal management, energy efficiency, and system performance. Overall, the meta-cooling control loops 408 ensures the hybrid cooling system 112 operates optimally across a wide range of operational scenarios, maximizing cooling efficiency while minimizing energy consumption and wear on the cooling components 258 and/or electronic components 250.

The system control circuitry 204 of the hybrid cooling controller 202 comprises a cooling projection module 410. The cooling projection module 410 is a specialized component designed to predict future cooling requirements and thermal conditions of the electronic components 250, electronic devices 114, and/or edge compute system 106 using the hybrid cooling system 112. The cooling projection module 410 leverages computational algorithms, historical data, and real-time operational parameters to forecast potential thermal scenarios and determine the most efficient and effective cooling strategies ahead of time. For example, the cooling projection module 410 may perform thermal trend analysis by analyzing past and current thermal data to identify trends and patterns, which can indicate how system temperatures may change under various operational loads and environmental conditions. The cooling projection module 410 may perform predictive modeling by using mathematical models and simulations to predict future thermal states based on variables such as system workload, ambient temperature, and cooling system performance. This can involve ML algorithms 314 to train ML models 316 on telemetry data 430, such as historical temperature and performance data, stored in a telemetry database 420. The cooling projection module 410 may perform efficiency optimization by recommending adjustments to the hybrid cooling system 112 (e.g., changes in fan speed, pump flow rate, or the activation/deactivation of certain cooling components 258) that preemptively counteract predicted thermal challenges. This ensures the system remains within optimal temperature ranges, avoiding overheating and maximizing energy efficiency. The cooling projection module 410 may provide data-driven insights and recommendations to cooling system managers or automated control systems, enabling informed decisions about the best cooling strategies to implement in advance of thermal events. By incorporating a cooling projection module 410, the hybrid cooling system 112 becomes more proactive in its approach to thermal management, enhancing its ability to maintain stability and performance while reducing the risk of thermal-related failures and optimizing energy consumption.

The system control circuitry 204 of the hybrid cooling controller 202 comprises an ML training logic 412. The cooling projection module 410 may implement ML training logic 412 to train an ML model 316 to assist in its operation by following a systematic process that involves gathering data, preprocessing, model selection, training, and validation. For example, the ML training logic 412 collects, or accesses from a telemetry database 420, telemetry data 430 comprising a wide range of historical and real-time data from the sensors 242 relevant to operation and thermal conditions for the hybrid cooling system 112, the electronic components 250, the cooling components 258, the electronic devices 114, the cooling zones 234, the cooling units 222, the resource distribution unit 210, the cooling distribution unit 212, the power distribution unit 214, and so forth. The telemetry data can include temperature readings from various sensors 242, system workloads, cooling system settings (e.g., fan speeds, coolant flow rates), and environmental conditions (e.g., ambient temperature, humidity). The ML training logic 412 cleans and normalizes the raw data to remove outliers, fill in missing values, and ensure consistency. The ML training logic 412 identifies and selects features that significantly influence the cooling requirements, such as time of day, seasonal variations, and operational loads, are identified and prepared for use in training the model. The ML training logic 412 may combine the features to create new features from the existing data that can help improve model accuracy. Features might include historical averages, temperature gradients, or derived indicators of system performance. The ML training logic 412 may select different types of ML models based on the nature of the prediction problem and the characteristics of the data. For cooling prediction, ML models that excel in time series forecasting, such as Long Short-Term Memory (LSTM) neural networks, might be chosen for their ability to capture temporal dependencies and patterns in data. The selected model is trained using the prepared training dataset 422. The training process involves adjusting model parameters so that it can accurately predict future thermal conditions based on past and present data. This operation may involve dividing the data into training and test sets to evaluate the model's performance and prevent overfitting. After training, the ML training logic 412 assesses a predictive accuracy of the trained ML model 316 using a separate subset of data not seen by the model during training. The ML training logic 412 may use performance metrics such as mean squared error (MSE) or mean absolute error (MAE) to evaluate the quality of the predictions. Based on performance evaluations, the ML training logic 412 might refine the ML model 316 through further iterations of training, feature engineering, or model adjustment to improve accuracy and reliability. The ML training logic 412 continues to train the ML model 316 using new training data over time, adjusting its predictions based on actual outcomes to improve its accuracy and adapt to changing conditions.

The system control circuitry 204 of the hybrid cooling controller 202 comprises an ML training logic 412. Once the ML training logic 412 trains and tests the ML model 316, the ML training logic 412 deploys the ML model 316 to support the ML inferencing logic 414. This process enables the ML inferencing logic 414 to support the cooling projection module 410 to accurately forecast future cooling requirements and thermal conditions, facilitating proactive adjustments to the hybrid cooling system 112 for optimal performance and energy efficiency.

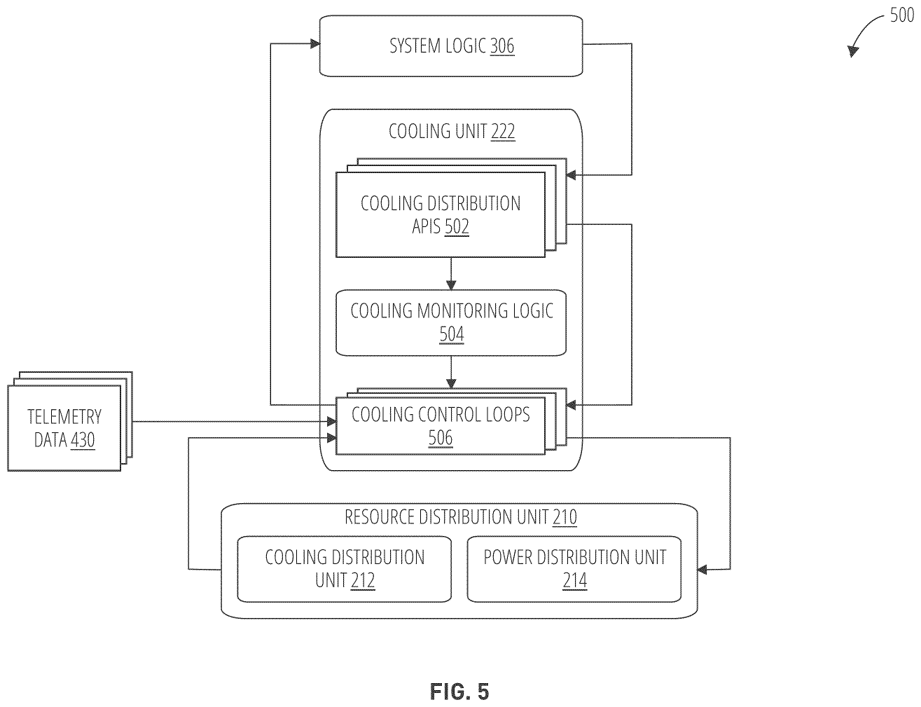

FIG. 5 illustrates a logic diagram 500 suitable for a cooling unit 222 of the hybrid cooling system 112. The logic diagram 500 comprises a more detailed architecture for a system control circuitry 204 interoperating with a resource distribution unit 210 and a cooling unit 222 of the hybrid cooling system 112.

As depicted in FIG. 5, the logic diagram 500 comprises system logic 306 of the system control circuitry 204 to coordinate operations of a cooling unit 222 and a resource distribution unit 210. The cooling unit 222 may implement circuitry and memory units, similar to the system control circuitry 204 and the memory unit 206, to interact with the system logic 306 of the system control circuitry 204 and the resource distribution unit 210. The cooling unit 222 of the hybrid cooling system 112 comprises a set of cooling distribution APIs 502, a cooling monitoring logic 504, and a set of cooling control loops 506.

The cooling unit 222 of the hybrid cooling system 112 comprises a set of cooling distribution APIs 502. Similar to the meta-control APIs 404, the cooling distribution APIs 502 are software interfaces that provide a high-level control mechanism over the cooling components 258 of the hybrid cooling system 112. For example, the hybrid cooling controller 202 may use the cooling distribution APIs 502 to control operations of the cooling components 258 of the hybrid cooling system 112 in accordance with system policies of the hybrid cooling system 112. The cooling distribution APIs 502 enable dynamic management and adjustment of cooling methodologies in response to control directives from the hybrid cooling controller 202. The cooling distribution APIs 502 facilitate seamless transitions between different cooling components 258, such as an air cooling component of an air cooling system and a liquid cooling component of a liquid cooling system. The cooling distribution APIs 502 optimize performance of the cooling components 258, and ensures optimal thermal management across different operational states of an electronic device 114 or a set of electronic devices 114.

The cooling unit 222 of the hybrid cooling system 112 comprises a cooling monitoring logic 504. The cooling monitoring logic 504 refers to software logic or algorithms designed to continuously analyze, assess, and respond to the cooling requirements of the electronic device 114 that utilize the cooling components 258 for the cooling zones 234 within the device chassis 232. The cooling monitoring logic 504 ensures the cooling component 258 operates efficiently and effectively under varying operational conditions. By gathering data from sensors 242 (e.g., temperature sensors, flow rate sensors) embedded in the cooling zones 234 within the device chassis 232 of the electronic device 114, the cooling monitoring logic 504 can make informed decisions about when to activate or deactivate each cooling component 258, how to adjust parameters such as fan speed or coolant flow rate, and identify an optimal cooling strategy to maintain the electronic components 250 within desired thermal thresholds. Additionally, the cooling monitoring logic 504 can predict thermal trends and preemptively adjust cooling strategies before temperatures reach critical levels, enhancing reliability and performance of the cooling components 258 and/or the electronic components 250.

The cooling unit 222 of the hybrid cooling system 112 comprises a set of cooling control loops 506. The cooling control loops 506 represent a structured, algorithmic framework designed to regulate the operation of the cooling components 258 for different electronic components 250. The cooling control loops 506 operate on telemetry data 430 continuously collected from the sensors 242, such as temperature, humidity, and airflow sensors. The cooling control loops 506 use this data to make real-time decisions on the most efficient cooling strategy to employ at any given moment. For example, the cooling control loops 506 involve sensing and collecting real-time data related to performance of the cooling components 258 and/or the electronic components 250, as well as environmental conditions affecting cooling efficiency. This includes temperatures at various points, coolant flow rates, air velocity, and external temperatures. The collected data is then processed by control loop logic, which often involves sophisticated algorithms or ML models capable of analyzing trends, predicting future states, and making decisions on how to adjust cooling parameters. This operation determines an amount of cooling is optimal for current conditions. Based on the decision-making process, the cooling control loops 506 send commands to the cooling components 258, such as actuators, pumps, valves, and fans, adjusting their operation to implement the chosen cooling strategy. For example, it may increase the fan speed for air cooling, adjust a flow rate of the cooling fluid 216 for liquid cooling, or engage both systems to varying degrees. The outcome of these adjustments is monitored to provide feedback into the cooling control loops 506, enabling them to continuously refine their decisions and adapt to changing conditions. This closed-loop operation ensures optimal thermal management, energy efficiency, and system performance. Overall, the cooling control loops 506 ensures the cooling components 258 operate optimally across a wide range of operational scenarios, maximizing cooling efficiency while minimizing energy consumption and wear on the cooling components 258 and/or electronic components 250.

The cooling control loops 506 may interact with the system logic 306 and the resource distribution unit 210. The system logic 306 implements system-level control over the hybrid cooling system 112, such as in response to control directives from the system orchestration logic 402. The system logic 306 generates and sends control directives to the resource distribution unit 210 and the cooling units 222. In one embodiment, for example, the operation of the resource distribution unit 210 operates within the meta-cooling control loops 408. In one embodiment, for example, the operation of the resource distribution unit 210 operates within the cooling control loops 506. In one embodiment, for example, the operation of the resource distribution unit 210 operates within both the meta-cooling control loops 408 and the cooling control loops 506.

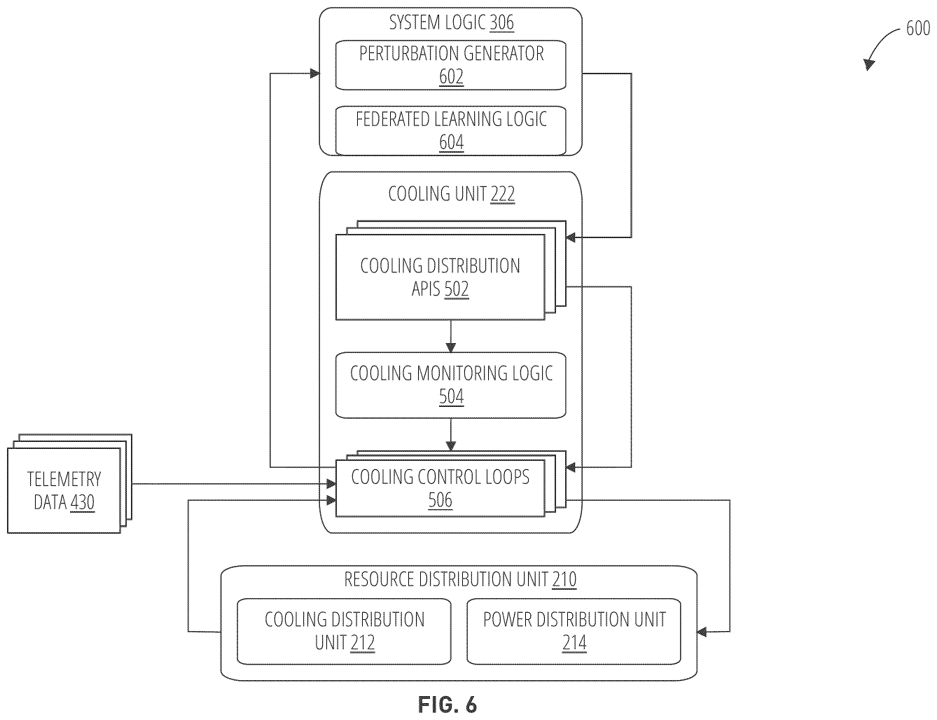

FIG. 6 illustrates a logic diagram 600 suitable for a system logic 306 and/or a cooling unit 222 of the hybrid cooling system 112. The logic diagram 600 comprises a more detailed architecture for the system logic 306 of the system control circuitry 204 interoperating with a resource distribution unit 210 and a cooling unit 222 of the hybrid cooling system 112.

As previously described, the hybrid cooling system 112 may utilize or have access to an AI system 110 to assist in managing cooling operations. The AI system 110 may implement one or more ML algorithms to train one or more ML models 316. For example, an ML model 316 may receive as input configuration data for the hybrid cooling system 112 and hybrid cooling subsystems 122, and generate one or more metrics for the hybrid cooling system 112 or hybrid cooling subsystem 122 based on the configuration data. The configuration data may comprise a set of system parameters or system rules associated with the hybrid cooling system, such as cooling subsystems, electronic components, electronic devices, electronic systems, networks, and so forth. Non-limiting examples of parameters include parameters with values representing an amount of cooling fluid, a type of cooling fluid, a velocity of movement of the cooling fluid, an amount of power for a cooling subsystem, an amount of cooling capacity for a cooling subsystem, and so forth. The ML model 316 may analyze the set of parameters, and it generates a metric for the hybrid cooling system 112 based on the set of parameters. Non-limiting examples of metrics include measurement values, key performance indicators (KPIs), operational metrics, system metrics, and so forth. For example, a metric may comprise measurement values representing aging of system components, resource utilization, system energy efficiency, system workloads, operating conditions, environment conditions, ambient conditions, service level objectives against workloads, and so forth.

The AI system 110 may systematically and automatically test the hybrid cooling system 112 in an attempt to optimize resource allocation and thermal management operations of the hybrid cooling system 112. For example, the AI system 110 may modify the various system parameters or system rules of the hybrid cooling system 112 to observe effects on the hybrid cooling system 112 through changes to the metrics. Through a series of iterations, the AI system 110 converges on a set of system parameters or system rules optimized for the hybrid cooling system 112. The AI system uses the system parameters to update cooling policies for the hybrid cooling system 112. The ML model 316, system parameters, system rules, and/or cooling policies can be shared with other hybrid cooling systems 112 through a federated system using, for example, peer-to-peer (P2P) communications through a public or private network.

As depicted in FIG. 6, the logic diagram 600 comprises the system logic 306 interacting with the cooling unit 222 and the resource distribution unit 210. The system logic 306 comprises a perturbation generator 602 and federated learning logic 604. The system logic 306 uses the perturbation generator 602 as a learning engine that discovers over time how to optimize different KPIs for the hybrid cooling system 112. Non-limiting examples of KPIs include energy consumption, lifetime of the system, aging of system resources (e.g., XPU aging speed), resource utilization, system energy efficiency, SLO for workloads, and so forth. The system logic 306 uses the federated learning logic 604 to support a distributed federated system with other systems, such as different edge compute systems 106, each utilizing a different hybrid cooling system 112. The federated learning logic 604 allows the different edge compute systems 106 to collaborate and learn better ways to optimize KPIs by trying different cooling policies under different circumstances.

The system logic 306 comprises a perturbation generator 602. The system control circuitry 204 of the hybrid cooling controller 202 can modify various settings for the hybrid cooling system 112 via one or more APIs, such as the meta-control APIs 404 and/or the cooling distribution APIs 502. The settings control operations of the hybrid cooling system 112, such as how much cooling fluid 216 to distribute, a speed or volume of cooling fluid 216 per unit of time that moves through fluid pipes to the cooling components 258, which electronic devices 114 are cooled and how, and so forth. The perturbation generator 602 generates small perturbations using the meta-control APIs 404 and/or the cooling distribution APIs 502 so that the federated learning logic 604 can observe the effect of such changes as measured against various KPIs. For example, assume the perturbation generator 602 changes a coolant target temperature from 30 degrees Celsius (C) to 29 degrees C. The federated learning logic 604 receives and analyzes the telemetry data 430 from the sensors 242, and compares the telemetry data 430 to one or more KPIs. If the federated learning logic 604 observes violations of the one or more KPIs, it may revert after some time period of time to a previous known configuration that previously satisfied the one or more KPIs. For example, the perturbation generator 602 may revert the change of 29 degrees C. to 30 degrees C. for the coolant target temperature because a KPI for a video analytic workload running on an electronic component 250 (e.g., an XPU) reduced from 30 frames per second (fps) to 26 fps. The perturbation generator 602 stores the different configurations and results into a storage media, such as the controller database 418, for example.

The system logic 306 comprises federated learning logic 604. The federated learning logic 604 is responsible for processing raw data generated by the perturbation generator 602. The federated learning logic 604 applies transfer learning and federated learning on top of the ML model 316 that is used to generate cooling policies to manage the hybrid cooling system 112. The federated learning logic 604 may execute at more favorable times to reduce impact on the hybrid cooling system 112 and/or the electronic devices 114, such as night or low-valley compute periods, when ambient temperatures are better and energy efficiency is high, when an amount of renewable energy is high, and so forth. The federated learning logic 604 updates the ML model 316 that is used to establish the cooling policies. Different ML models 316 may be used for different operating conditions or system configurations. Operating conditions can be defined by parameters such as a load on a system, ambient temperatures, workloads on an electronic device 114, and so forth. Using different smaller ML models 316 for different conditions may learn different optimization techniques, which can be combined into a larger ML model 316.

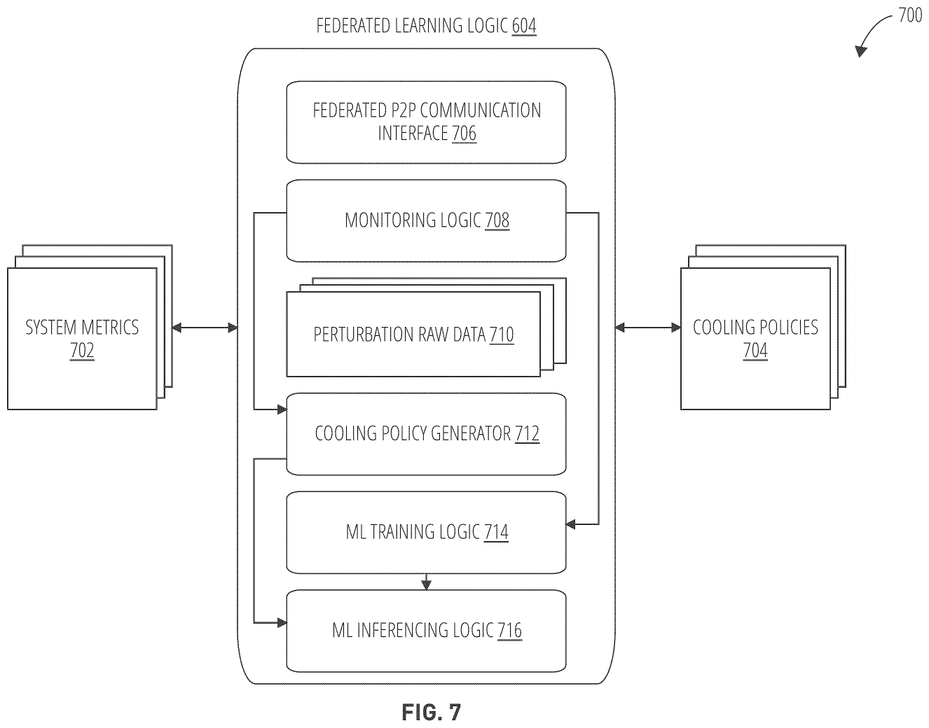

FIG. 7 illustrates a logic diagram 700. The logic diagram 700 illustrates a more detailed example for the federated learning logic 604 of the hybrid cooling system 112.

As depicted in FIG. 7, the logic diagram 700 illustrates the federated learning logic 604 receiving or retrieving one or more system metrics 702 for the hybrid cooling system 112. The federated learning logic 604 generates a set of one or more cooling policies 704 for the hybrid cooling system 112 based on the system metrics 702. The federated learning logic 604 comprises a federated P2P communication interface 706, a monitoring logic 708, perturbation raw data 710, a cooling policy generator 712, an ML training logic 714, and an ML inferencing logic 716.

The federated learning logic 604 controls federated learning for the edge compute system 106. Federated learning refers to a machine learning approach that enables the model to learn from data distributed across multiple devices or servers without requiring the data to be shared or centralized. This technique allows for privacy-preserving data analysis and model training, as the raw data remains on the local devices and only model updates or gradients are communicated to a central server for aggregation. The updated global model is then shared with all participating devices. This collaborative learning process improves the model with data from diverse sources, enhancing its accuracy and robustness while maintaining data privacy and security.

The federated learning logic 604 shares the ML models 316 with other peer systems in a system infrastructure using federated P2P communication interface 706. The federated learning logic 604 shares with peer systems newly discovered models. The list of peers may be registered by the infrastructure owner. Peers may be, for example, different base stations in a wireless communications system or different edge compute systems 106. The federated learning logic 604 may evaluate whether a new version of ML models 316 provided by peers perform well enough to replace local versions. For this function, the federated learning logic 604 may have some testing datasets to evaluate new coming models. These datasets are created by the hybrid cooling systems 112 during a life time of the system and they cover different conditions and the impact of perturbations to the system metrics 702. The federated learning logic 604 use the datasets to evaluate the accuracy of new models for a current deployment. The ML models 316 are updated based on evaluation results.

The federated learning logic 604 comprises monitoring logic 708 to monitor a set of system metrics 702 and a current state for the hybrid cooling system 112. The monitoring logic 708 refers to software logic or algorithms designed to continuously analyze, assess, and respond to the cooling requirements of the hybrid cooling system 112. The monitoring logic 708 ensures the hybrid cooling system 112 operates efficiently and effectively under varying operational conditions generated by the perturbation generator 602. By gathering data from sensors 242 (e.g., temperature sensors, flow rate sensors) embedded in the cooling zones 234 within the device chassis 232 of the electronic device 114, the monitoring logic 708 can make informed decisions about when to activate or deactivate each cooling unit 222, how to adjust parameters such as fan speed or coolant flow rate, and identify an optimal cooling strategy to maintain the system within desired thermal thresholds, and adjust existing cooling policies 704. Additionally, the monitoring logic 708 can predict thermal trends and preemptively adjust cooling strategies before temperatures reach critical levels, enhancing system reliability and performance.

The federated learning logic 604 is responsible for processing perturbation raw data 710 generated by the perturbation generator 602. The federated learning logic 604 applies transfer learning and federated learning on top of the ML model 316 that is used to generate cooling policies 704 to manage the hybrid cooling system 112.

The federated learning logic 604 comprises a cooling policy generator 712. The cooling policy generator 712 receives as input the perturbation raw data 710 and compares it to the system metrics 702. The cooling policy generator 712 analyzes the results, and it generates and/or updates the cooling policies 704 for the hybrid cooling system 112. The cooling policy generator 712 may periodically activate the perturbation generator 602 to discover new states to generate and/or update the cooling policies 704 for the hybrid cooling system 112.

The federated learning logic 604 may implement ML training logic 714 to generate and/or update an ML model 316 for an ML inferencing logic 716 used by the cooling policy generator 712 to establish the cooling policies 704. Similar to the ML training logic 412 and the ML inferencing logic 414, the ML training logic 714 may use training dataset 422 derived from telemetry data 430 to train different ML models 316 that may be used for different operating conditions or system configurations of the hybrid cooling system 112. Operating conditions can be defined by parameters such as a load on a hybrid cooling system 112, ambient temperatures, workloads on an electronic device 114, and so forth. Using different smaller ML models 316 for different conditions may result in learning different optimization techniques, which can be combined into a larger ML model 316. The trained ML model 316 may be deployed as part of the ML inferencing logic 716 to support the cooling policy generator 712.

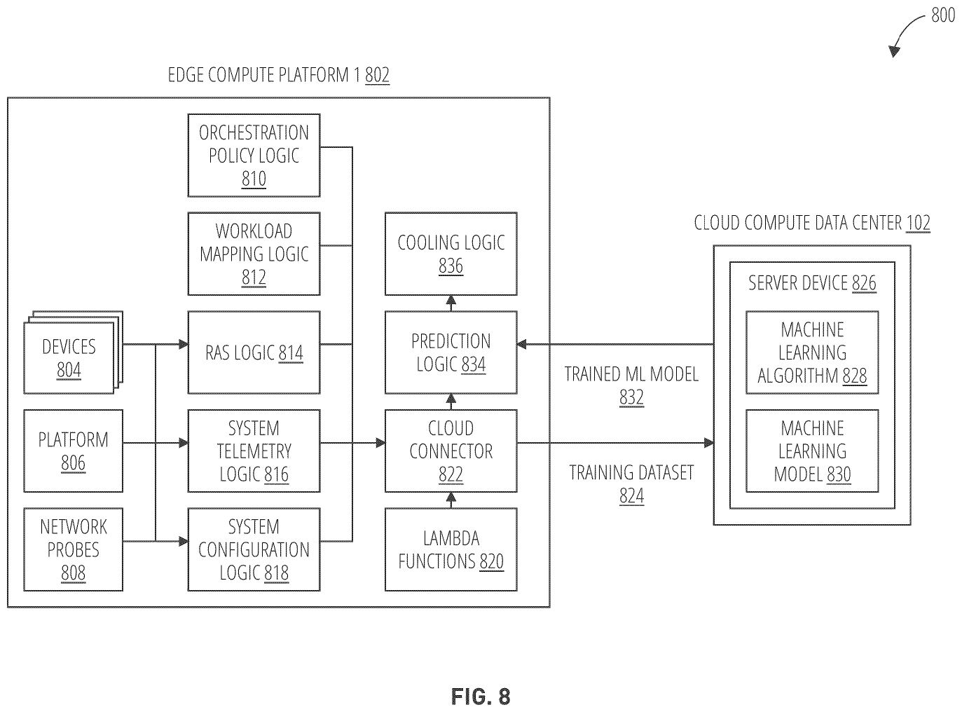

FIG. 8 illustrates a logic diagram 800. The logic diagram 800 is an example of an architecture or framework for federated learning of an edge compute system 106. Specifically, the logic diagram 800 is an example architecture for a system comprising a set of electronic devices suitable for implementing the system 100, the cooling system 200, the apparatus 300, the logic diagram 400, the logic diagram 500, the logic diagram 600, and/or the logic diagram 700. For example, the edge compute system 106 comprises an edge compute platform 1 802, which is similar to the edge compute platform 108 of the edge compute system 106 as described with reference to FIG. 1. The edge compute platform 108 is part of a cloud computing architecture for the edge compute system 106 utilizing a distributed AI system 110 to manage and control various aspects of the hybrid cooling system 112 for thermal management of the various electronic devices 114 as described herein.

As depicted in FIG. 8, the logic diagram 800 comprises the cloud compute data center 102 and an edge compute platform 1 802 communicating through the network 104. The edge compute platform 1 802 is an example of the edge compute platform 108 as described with reference to FIG. 1. As with the edge compute platform 108, the edge compute platform 1 802 may offer edge services to a set of electronic devices 114.

Further, the edge compute platform 1 802 comprises a set of devices 804. The devices 804 may comprise, discrete electronic devices, such as edge devices. An edge device in the context of edge computing is a piece of hardware that controls data flow at the boundary between two networks. These devices are used for processing, collecting, and analyzing data near the source of data generation, rather than sending the data across a network to a data center or cloud for processing. This proximity to data sources allows for real-time, or near real-time, computing and decision-making, reducing latency and bandwidth use. Edge devices can range from simple sensors and actuators to more complex computing devices like smart routers, IoT devices, smartphones, and gateways. The key characteristic of an edge device is its ability to perform local computation on the data it collects before potentially sending it on to central data centers or clouds for further processing or storage, such as cloud compute data center 102, for example.

The edge compute platform 1 802 comprises a platform 806. The platform 806 is a suite of tools and technologies designed to facilitate the development, deployment, management, and operation of applications and services at the edge of the network. An edge platform aims to streamline the complexities associated with edge computing, such as handling heterogeneous devices, managing distributed data, ensuring security, and optimizing resources across various edge locations. To this end, the platform 806 may include software and hardware supporting: development tools to create edge applications, an execution environment for running edge applications which could involve containerization or virtualization technologies to ensure applications are portable and isolated from one another; data management capabilities for efficiently handling data at the edge such as data collection, processing, aggregation, and potentially synchronization with centralized cloud services or data centers; networking interfaces for secure and reliable communication between edge devices, and between edge devices and central systems, possibly incorporating features like network slicing for bandwidth optimization; device management tools for remotely managing and configuring edge devices, including software updates, monitoring, and fault management to ensure the health and security of the edge infrastructure; and integrated security features to protect the edge platform and its devices from cyber threats, such as encryption, identity and access management, and intrusion detection systems.

The edge compute platform 1 802 comprises a set of network probes 808. The network probes 808 are devices or software tools designed to actively monitor, analyze, and collect data about the network's performance and health. The network probes 808 are strategically deployed at various points within an edge computing infrastructure to gather real-time metrics such as bandwidth usage, latency, packet loss, and overall network traffic patterns. Their primary objective is to ensure the optimal operation of the network, which is critical for the functionality and efficiency of edge computing systems where data is processed close to the source of generation. The network probes 808 perform functions such as measuring various performance metrics to identify potential bottlenecks or degradation in network service levels that could impact edge applications, detecting and diagnosing network problems and failures proactively to minimize downtime and service disruption, monitoring network traffic for unusual patterns or activities that could indicate security threats such as intrusions or malware spreading within the edge infrastructure, providing insights into the type, volume, and flow of data across the network to aid in capacity planning, network optimization, and ensuring quality of service for critical applications, assisting in the deployment of new network configurations, updates, or patches by validating their performance and ensuring they do not adversely affect the network.

The edge compute platform 1 802 also includes a set of components and/or devices to implement various types of logic for supporting various edge services and features. For example, the edge compute platform 1 802 includes an orchestration policy logic 810, a workload mapping logic 812, a RAS logic 814 (reliability-availability-serviceability), a system telemetry logic 816, and a system configuration logic 818. The orchestration policy logic 810 implements one or more orchestration policies for the edge compute system 106. An orchestration policy comprises a set of rules or guidelines designed to manage and coordinate the configuration, provision, and deployment of resources and services across an edge computing environment. These policies enable automated decision-making regarding where, when, and how computing tasks are executed within the distributed framework of an edge network, considering factors like resource availability, network conditions, application requirements, and security constraints. The workload mapping logic 812 implements algorithms or methodologies used to determine how and where various computing tasks or workloads are assigned and executed within an edge computing architecture. This logic is used for maximizing the efficiency, performance, and reliability of an edge network by ensuring that workloads are processed in the most appropriate location, considering factors such as the type of task, resources required, latency constraints, and network traffic conditions. The RAS logic 814 implements logic for reliability, availability, and serviceability (RAS) attributes for systems operating at the edge of a network due to their often remote, autonomous nature and their need for high reliability in processing data near its source. The system telemetry logic 816 manages system telemetry data for an edge system, which includes the automated collection, transmission, and analysis of data regarding the performance, health, and behavior of the computing devices, software, and networks that constitute the edge computing environment. This data is used for monitoring, managing, and optimizing system performance and ensuring the reliability and security of edge operations. The system configuration logic 818 controls setup and management of hardware, software, network settings, and policies that determine how an edge computing environment operates. This includes specifying and arranging the components of the system to work together efficiently to process, store, and transmit data as intended.

Further, the logic diagram 800 depicts an example of the edge compute platform 1 802 and the cloud compute data center 102 implementing various types of logic and components of the AI system 110. As depicted in the logic diagram 800, the edge compute platform 1 802 may implement a set of lambda functions 820, a cloud connector 822, prediction logic 834, and cooling logic 836. The cloud compute data center 102 may implement logic for an ML algorithm 314 and an ML model 316.

The edge compute platform 1 802 may implement a set of one or more lambda functions 820. A lambda function is a relatively small, anonymous function defined with the lambda keyword in programming languages like Python. It is often used in machine learning code for conciseness and flexibility, especially in data manipulation and feature engineering phases. A lambda function in Python allows the function to take any number of arguments but comprises only one expression, the result of which is returned by the function. In machine learning, Lambda functions are frequently used in data preprocessing steps to apply transformations to data elements. For example, a lambda function may convert temperatures from Celsius to Fahrenheit across a dataset. When creating or modifying features in a dataset, lambda functions can apply quick, inline calculations or transformations without the need for defining a separate, named function. Lambda functions are often used with map( ) filter( ) and reduce( ) functions to apply operations on lists or columns in a DataFrame. For instance, applying a lambda function to scale a numerical feature in a pandas DataFrame column.

The edge compute platform 1 802 may implement the lambda functions 820 to pre-process data from various logic or components of the edge compute platform 1 802, such as the orchestration policy logic 810, the workload mapping logic 812, the RAS logic 814, and system telemetry logic 816, and/or the system configuration logic 818. The output of the lambda functions 820 is a training dataset 824 suitable for training an ML model, such as the ML model 830 of the cloud compute data center 102. The cloud connector 822 collects the output from the lambda functions 820, employs a set of filters to filter the output from the lambda functions 820 to limit the output to a dataset suitable for inclusion in the training dataset 824, and outputs the training dataset 824 to a server device 826 of the cloud compute data center 102.

The cloud compute data center 102 comprises a set of servers, such as a server pool or server farm, as represented by the server device 826. The server device 826 executes an ML algorithm 828 to train an ML model 830 using the training dataset 824. Once the ML model 830 is trained, the server device 826 sends a trained ML model 832 to the edge compute platform 1 802 for deployment by the prediction logic 834 to perform inferencing operations to support the cooling logic 836.

Once the ML algorithm 828 sufficiently trains and tests the ML model 830, the server device 826 sends the trained ML model 832 to the edge compute platform 1 802 for deployment by the prediction logic 834.

The prediction logic 834 receives as input data from one or more outputs of the various types of logic implemented by the edge compute platform 1 802, such as the orchestration policy logic 810, the workload mapping logic 812, the RAS logic 814, the system telemetry logic 816, and/or the system configuration logic 818. The prediction logic 834 analyzes the input data, and it generates a prediction for the hybrid cooling system 112, as previously described. The training dataset 824 is updated with new training data, and the ML algorithm 828 re-trains the ML model 830 with the updated training dataset 824. This feedback loop ensures the predictions are periodically updated with current data, thereby increasing accuracy of the predictions made by the prediction logic 834. The prediction logic 834 outputs the predictions to the cooling logic 836.

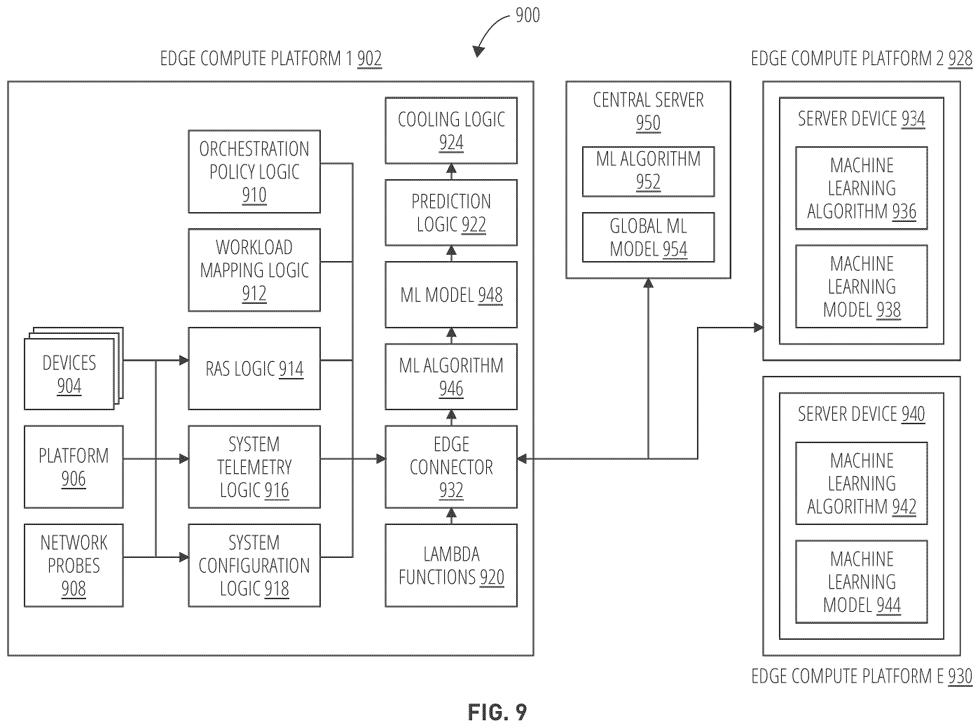

FIG. 9 illustrates a logic diagram 900. The logic diagram 900 is an example architecture for a system comprising a set of electronic devices suitable for implementing the system 100, the cooling system 200, the apparatus 300, the logic diagram 400, the logic diagram 500, the logic diagram 600, the logic diagram 700, and/or the logic diagram 800. For example, the edge compute system 106 comprises an edge compute platform 1 802, which is similar to the edge compute platform 108 of the edge compute system 106 as described with reference to FIG. 1. Specifically, the logic diagram 900 is a more detailed example of a federated architecture for an edge computing system utilizing a distributed AI system 110 to manage and control various aspects of the hybrid cooling system 112 of the various electronic devices 114 as described herein.

As depicted in FIG. 9, the logic diagram 900 comprises multiple edge compute platforms 108 operating together in a federated model. For example, the logic diagram 900 comprises an edge compute platform 1 902, an edge compute platform 2 928, and an edge compute platform E 930, where E represents any positive integer, all communicating through the network 104. As with the edge compute platform 1 802, the edge compute platform 1 902, the edge compute platform 2 928 and the edge compute platform E 930 may offer edge services to a set of electronic devices 114, such as electronic device 1 116, electronic device 2 118, and electronic device C 120, in different geographic regions or locations.

A federated model for an edge system refers to the implementation of Federated Learning (FL) in an edge computing environment. Federated Learning is a machine learning approach that enables a model to be trained across multiple decentralized edge devices or servers holding local data samples, without exchanging them. This method addresses privacy concerns, reduces the need for large centralized data storage, and minimizes the bandwidth needed to transmit large datasets. In an edge computing context, federated models leverage the computation and data storage capabilities of edge devices (such as smartphones, IoT devices, and edge servers) to perform local computations on data. These devices work collaboratively to improve a shared machine learning model by keeping the data localized, thereby enhancing privacy and efficiency. A federated model provides several advantages for an edge system. For example, data remains on the device, reducing the risk of privacy breaches. Only model updates are transmitted, not the raw data, significantly reducing the amount of data sent over the network. Federated learning can easily scale to accommodate more devices without a significant increase in central processing or storage requirements. Models can learn from data in real-time, adapting to new data trends and patterns as they occur in the edge environment. Federated models are particularly useful in scenarios where privacy is paramount, and the data is naturally decentralized, such as in healthcare, finance, telecommunications, and smart cities. Implementing federated learning in edge systems poses unique challenges, including handling device heterogeneity, dealing with uneven data distribution (data bias), and ensuring robust and secure model aggregation methods.

As depicted in FIG. 9, the logic diagram 900 comprises a central server 950 and multiple edge compute platforms 108. Each edge compute platform 108 may have an architecture similar to that shown for the edge compute platform 1 902. Further, each edge compute platform 108 may implement hardware and software components for an AI system 110. For example, the edge compute platform 1 902 implements a set of lambda functions 920, an edge connector 932, an ML algorithm 946, an ML model 948, prediction logic 922, and cooling logic 924. The edge connector 932, the ML algorithm 946 and the ML model 948 are similar to the cloud connector 822, the ML algorithm 828, and the ML model 830 as described with reference to FIG. 8. Similarly, the edge compute platform 2 928 implements a server device 934 for executing an ML algorithm 936 and an ML model 938, while the edge compute platform E 930 implements a server device 940 for executing an ML algorithm 942 and an ML model 944. The ML algorithm 936 and the ML algorithm 942 are similar to the ML algorithm 828, and the ML model 938 and ML model 944 are similar to the ML model 830.

The central server 950 implements an ML algorithm 952 and a global ML model 954. The ML algorithm 952 initializes and distributes the global ML model 954 to participating edge devices, such as edge compute platform 1 902, the edge compute platform 2 928, and the edge compute platform E 930, from the central server 950. Each edge device trains the model on its local data, creating a set of model updates that reflect the learning from that data. The model updates from all participating devices are sent back to the central server 950, where they are aggregated to produce an updated global ML model 954. This aggregation can be done in ways that further preserve privacy, such as using secure aggregation techniques. The updated global ML model 954 is then sent back to the edge devices, replacing the local models, and the process repeats for several cycles until the model converges or meets the desired performance criteria. For example, a trained version of the global ML model 954 is deployed as the ML model 316 for use by the prediction logic 834 to make predictions for the hybrid cooling system 112. The prediction logic 922 outputs the predictions to the hybrid cooling controller 202 for controlling and managing operations of the hybrid cooling system 112 for the electronic components 250 of the electronic devices 114.

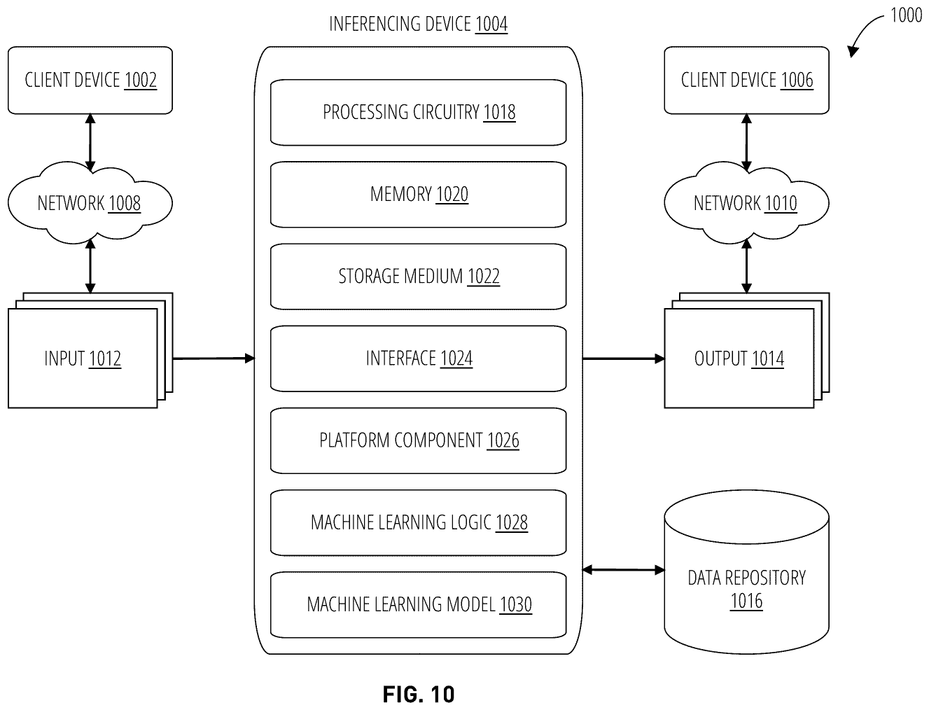

FIG. 10 illustrates an embodiment of a system 1000. The system 1000 is suitable for implementing one or more embodiments as described herein. In one embodiment, for example, the system 1000 is an AI/ML system suitable for supporting AI/ML techniques implemented for the hybrid cooling system 112, such as those described with reference to FIG. 1 through FIG. 9.

The system 1000 comprises a set of M devices, where M is any positive integer. FIG. 10 depicts three devices (M=3), including a client device 1002, an inferencing device 1004, and a client device 1006. The inferencing device 1004 communicates information with the client device 1002 and the client device 1006 over a network 1008 and a network 1010, respectively. The information may include input 1012 from the client device 1002 and output 1014 to the client device 1006, or vice-versa. In one alternative, the input 1012 and the output 1014 are communicated between the same client device 1002 or client device 1006. In another alternative, the input 1012 and the output 1014 are stored in a data repository 1016. In yet another alternative, the input 1012 and the output 1014 are communicated via a platform component 1026 of the inferencing device 1004, such as an input/output (I/O) device (e.g., a touchscreen, a microphone, a speaker, etc.).

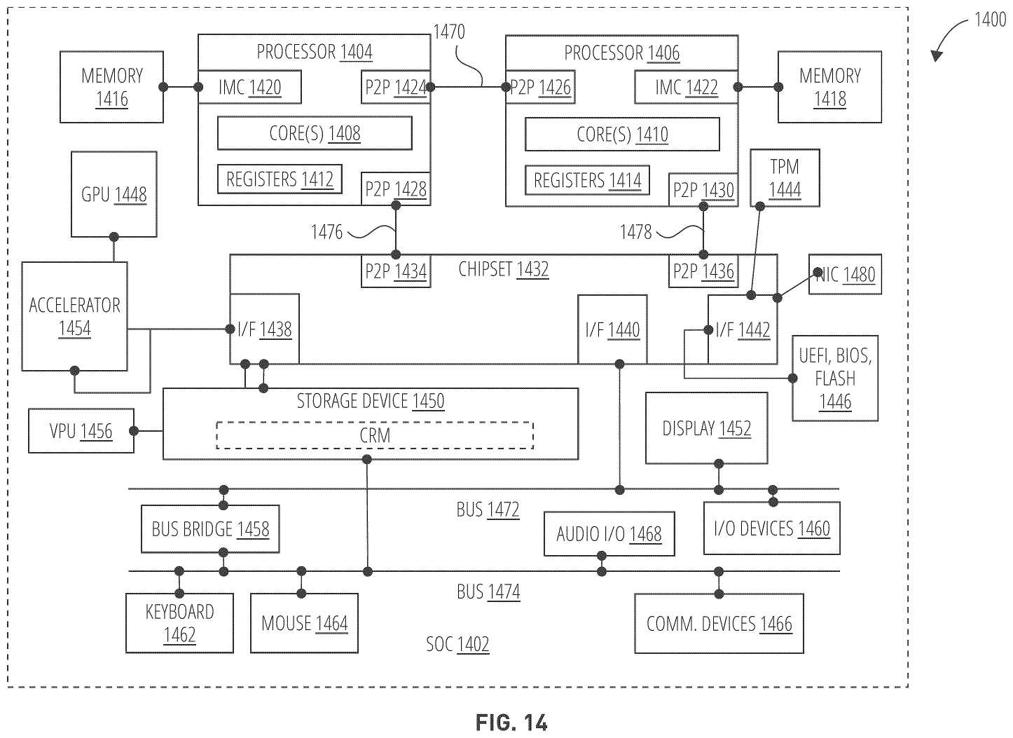

As depicted in FIG. 10, the inferencing device 1004 includes processing circuitry 1018, a memory 1020, a storage medium 1022, an interface 1024, a platform component 1026, ML logic 1028, and an ML model 1030. In some implementations, the inferencing device 1004 includes other components or devices as well. Examples for software elements and hardware elements of the inferencing device 1004 are described in more detail with reference to a computing architecture 1400 as depicted in FIG. 14. Embodiments are not limited to these examples.

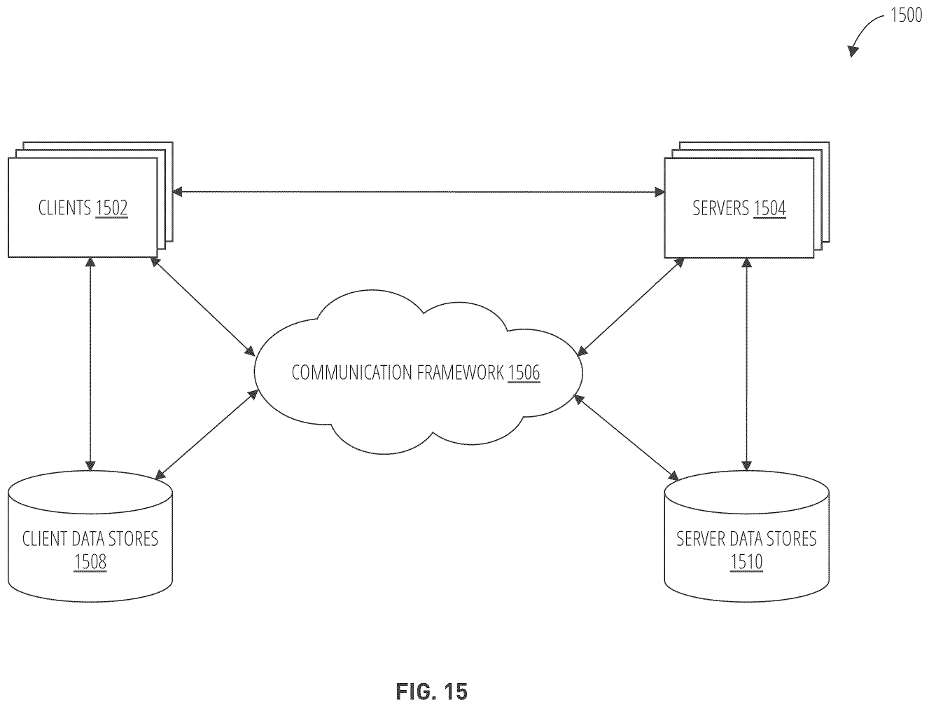

The inferencing device 1004 is generally arranged to receive an input 1012, process the input 1012 via one or more AI/ML techniques, and send an output 1014. The inferencing device 1004 receives the input 1012 from the client device 1002 via the network 1008, the client device 1006 via the network 1010, the platform component 1026 (e.g., a touchscreen as a text command or microphone as a voice command), the memory 1020, the storage medium 1022 or the data repository 1016. The inferencing device 1004 sends the output 1014 to the client device 1002 via the network 1008, the client device 1006 via the network 1010, the platform component 1026 (e.g., a touchscreen to present text, graphic or video information or speaker to reproduce audio information), the memory 1020, the storage medium 1022 or the data repository 1016. Examples for the software elements and hardware elements of the network 1008 and the network 1010 are described in more detail with reference to a communications architecture 1500 as depicted in FIG. 15. Embodiments are not limited to these examples.

The inferencing device 1004 includes ML logic 1028 and an ML model 1030 to implement various AI/ML techniques for various AI/ML tasks. The ML logic 1028 receives the input 1012, and processes the input 1012 using the ML model 1030. The ML model 1030 performs inferencing operations to generate an inference for a specific task from the input 1012. In some cases, the inference is part of the output 1014. The output 1014 is used by the client device 1002, the inferencing device 1004, or the client device 1006 to perform subsequent actions in response to the output 1014.

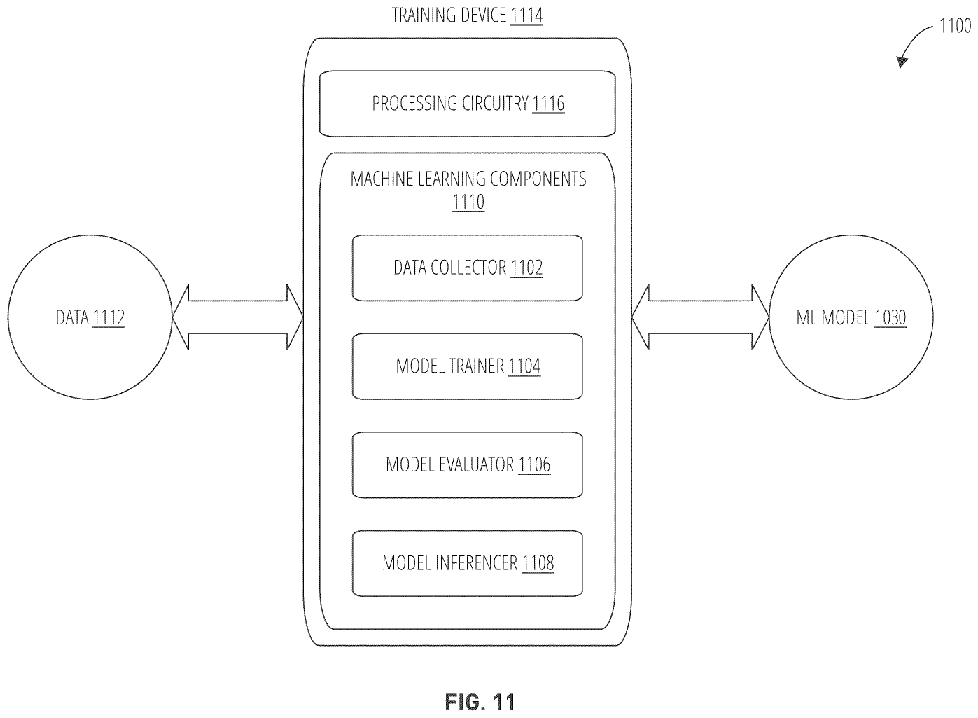

In various embodiments, the ML model 1030 is a trained ML model 1030 using a set of training operations. An example of training operations to train the ML model 1030 is described with reference to FIG. 11.

FIG. 11 illustrates an apparatus 1100. The apparatus 1100 depicts a training device 1114 suitable to generate a trained ML model 1030 for the inferencing device 1004 of the system 1000. As depicted in FIG. 11, the training device 1114 includes a processing circuitry 1116 and a set of ML components 1110 to support various AI/ML techniques, such as a data collector 1102, a model trainer 1104, a model evaluator 1106 and a model inferencer 1108.

In general, the data collector 1102 collects data 1112 from one or more data sources to use as training data for the ML model 1030. The data collector 1102 collects different types of data 1112, such as text information, audio information, image information, video information, graphic information, and so forth. The model trainer 1104 receives as input the collected data and uses a portion of the collected data as test data for an AI/ML algorithm to train the ML model 1030. The model evaluator 1106 evaluates and improves the trained ML model 1030 using a portion of the collected data as test data to test the ML model 1030. The model evaluator 1106 also uses feedback information from the deployed ML model 1030. The model inferencer 1108 implements the trained ML model 1030 to receive as input new unseen data, generate one or more inferences on the new data, and output a result such as an alert, a recommendation or other post-solution activity.

Operations for the disclosed embodiments are further described with reference to the following figures. Some of the figures include a logic flow. Although such figures presented herein include a particular logic flow, the logic flow merely provides an example of how the general functionality as described herein is implemented. Further, a given logic flow does not necessarily have to be executed in the order presented unless otherwise indicated. Moreover, not all acts illustrated in a logic flow are required in some embodiments. In addition, the given logic flow is implemented by a hardware element, a software element executed by one or more processing devices, or any combination thereof. The embodiments are not limited in this context.

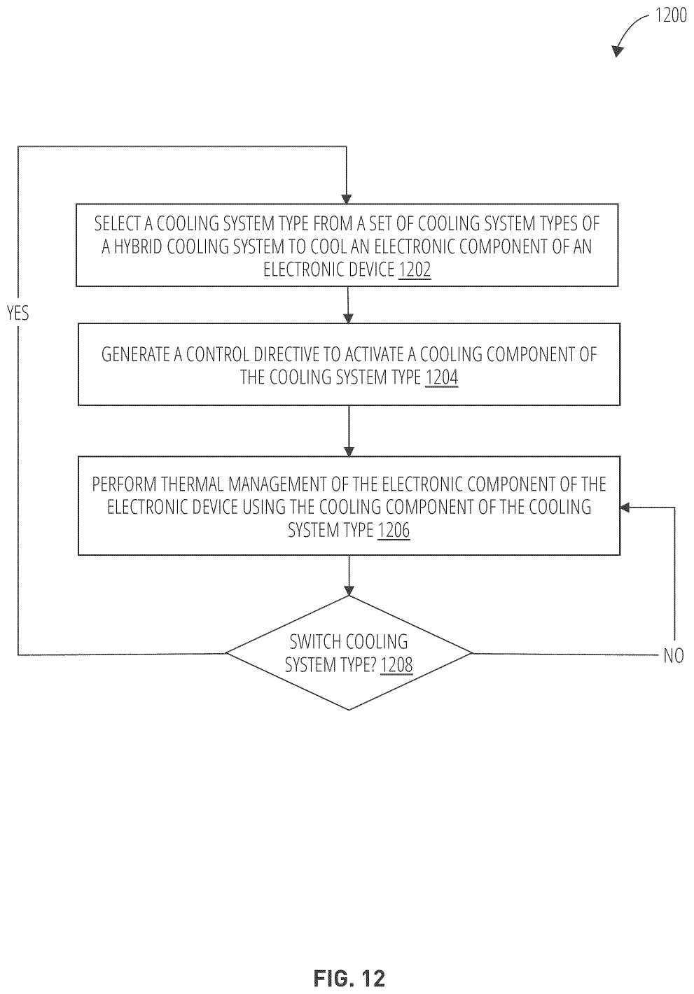

FIG. 12 illustrates an embodiment of a logic flow 1200. The logic flow 1200 is representative of some or all of the operations executed by one or more embodiments described herein. For example, the logic flow 1200 includes some or all of the operations performed by devices or entities within the system 100, cooling system 200, apparatus 300, logic diagram 400, logic diagram 500, logic diagram 600, logic diagram 700, logic diagram 800, logic diagram 900, system 1000, and/or apparatus 1100. In one embodiment, the logic flow 1200 is implemented as instructions stored on a non-transitory computer-readable storage medium, such as the storage medium 1022, that when executed by the processing circuitry 1018 causes the processing circuitry 1018 to perform the described operations. The storage medium 1022 and processing circuitry 1018 may be co-located, or the instructions may be stored remotely from the processing circuitry 1018. Collectively, the storage medium 1022 and the processing circuitry 1018 may form a system.

In block 1202, the logic flow 1200 selects a cooling system type from a set of cooling system types of a hybrid cooling system to cool an electronic component of an electronic device. In block 1204, the logic flow 1200 generates a control directive to activate a cooling component of the cooling system type. In block 1206, the logic flow 1200 performs thermal management of the electronic component of the electronic device using the cooling component of the cooling system type. In decision block 1208, the logic flow 1200 determines whether to switch to a different cooling system type. If yes, control passes to the block 1202 to restart the process. If no, control passes to the block 1206 to continue performing thermal management operations.

By way of example, the hybrid cooling controller 202 selects a cooling system type from a set of cooling system types of a hybrid cooling system 112 to cool an electronic component 250 of an electronic device 114. The hybrid cooling controller 202 generates a control directive to activate a cooling component 258 of the cooling system type. The resource distribution unit 210 receives the control directive, and it allocates resources to the a cooling unit 222 of the hybrid cooling subsystem 122 for the electronic device 114. The cooling unit 222 activates or deactivates a cooling component 258 of the cooling system type. The cooling component 258 performs thermal management of the electronic component 250 of the electronic device 114. For example, the set of cooling system types may comprise an air cooling system type or a liquid cooling system type. The hybrid cooling system 112 may comprise any number of different cooling system types, and embodiments are not limited to these examples.

When the hybrid cooling controller 202 selects an air cooling system type, the hybrid cooling controller 202 sends a control directive to the power distribution unit 214 of the resource distribution unit 210 to start delivery of power from the power supply 220. The resource distribution unit 210 then selects a cooling unit 222 from the hybrid cooling subsystem 122 that is part of an air cooling system of the air cooling system type. Assume the cooling unit 1 224 is part of the air cooling system. The cooling unit 1 224 selects a cooling component 258 that is a component of the air cooling system, such as cooling component 1 260 comprising a fan or series of fans distributed throughout the device chassis 232 of the electronic device 114. The cooling unit 1 224 sends a control directive to the cooling component 1 260 to activate the fans to begin cooling one or more of the electronic components 250, such as electronic component 1 252, for example.

When the hybrid cooling controller 202 selects a liquid cooling system type, the hybrid cooling controller 202 sends a control directive to the cooling distribution unit 212 of the resource distribution unit 210 to start delivery of cooling fluid 216 from the fluid reservoir 218. The resource distribution unit 210 then selects a cooling unit 222 from the hybrid cooling subsystem 122 that is part of a liquid cooling system of the liquid cooling system type. Assume the cooling unit 2 226 is part of the liquid cooling system. The cooling unit 222 selects a cooling component 258 that is a component of the liquid cooling system, such as cooling component 2 262 comprising an open or closed immersion tank within the device chassis 232 of the electronic device 114. The cooling unit 2 226 sends a control directive to the cooling component 2 262 to fill the liquid immersion fans with the cooling fluid 216 to begin cooling one or more of the electronic components 250, such as electronic component 250, for example.

The hybrid cooling controller 202 may select a cooling system type using a number of different techniques. For example, the meta-cooling monitoring logic 406 of the system control circuitry 204 may decode sensor data, such as telemetry data 430, obtained from a sensor 242 for the electronic component 250 of the electronic device 114. The hybrid cooling controller 202 may select the cooling system type from the set of cooling system types based on the sensor data. In another example, the hybrid cooling controller 202 may access a cooling policy from a set of cooling policies 704 for the hybrid cooling system 112. The cooling policy may include a set of operating rules for the hybrid cooling system 112. The hybrid cooling controller 202 may select the cooling system type from the set of cooling system types based on an operating rule of the cooling policy.

The hybrid cooling controller 202 may switch between different cooling system types based on an operating rule of a cooling policy. For example, the hybrid cooling controller 202 may access a cooling policy for the hybrid cooling system 112, where the cooling policy includes a set of operating rules for the hybrid cooling system 112. The hybrid cooling controller 202 may decide to select a different cooling system type from the set of cooling system types based on an operating rule of the cooling policy. For example, the operating rule may comprise a rule that switches from a liquid cooling system used in summer months to an air cooling system used in winter months to conserve resources for the edge compute system 106. The hybrid cooling controller 202 may generate a control directive to activate a cooling component 258 of the different cooling system type. The cooling component 258 may perform thermal management of the electronic component 250 of the electronic device 114 using the cooling component 258 of the different cooling system type.

The hybrid cooling controller 202 may switch between different cooling system types based on sensor data or telemetry data 430. For example, the hybrid cooling controller 202 may receive a set of system metrics 702 for the hybrid cooling system 112. The hybrid cooling controller 202 decodes a set of sensor data from a set of sensors 242 for multiple electronic devices 114 cooled by the hybrid cooling system 112 according to a cooling policy. The hybrid cooling controller 202 may compare the set of sensor data to the set of system metrics 702 to obtain a set of residual values, which represent a different between the sensor data and the system metrics 702. The hybrid cooling controller 202 may select a different cooling system type from the set of cooling system types of the hybrid cooling system 112 to cool the electronic component 250 of the electronic device based on the residual values. For example, assume an edge compute system 106 is located in a seasonal climate and is using an air cooling system during the summer months to converse power from the power supply 220. Further assume the telemetry data 430 indicates that the electronic component 250 of the electronic device 114 is approaching or exceeding thermal limits. The hybrid cooling controller 202 may switch from the air cooling system to the liquid cooling system to increase an amount of cooling delivered to the electronic component 250 of the electronic device 114. The cooling component 258 may perform thermal management of the electronic component 250 of the electronic device 114 using the cooling component 258 of the different cooling system type.

The hybrid cooling controller 202 may systematically and automatically test different operating rules for the hybrid cooling system 112 to optimize performance of the hybrid cooling system 112. For example, a system logic 306 of the system control circuitry 204 may comprise a perturbation generator 602 and a federated learning logic 604. The federated learning logic 604 receives a set of system metrics 702 for the hybrid cooling system 112. The federated learning logic 604 sends a control directive to the perturbation generator 602 in accordance with a modified operating rule from a cooling policy for the hybrid cooling system 112. The perturbation generator 602 sends a control directive to the cooling unit 222 to change cooling operations for one or more of the hybrid cooling subsystems 122 of one or more electronic devices 114. Sometime after the changes are implemented by the hybrid cooling system 112, the federated learning logic 604 may decode a set of sensor data such as perturbation raw data 710 from a set of sensors 242 for multiple electronic devices 114 cooled by the hybrid cooling system 112 according to the modified rule of the cooling policy. The federated learning logic 604 may compare the set of sensor data to the set of system metrics 702 to obtain a set of residual values. The federated learning logic 604 may determine whether to retain or discard the modified rule of the cooling policy for the hybrid cooling system 112 based on an analysis of the residual values. If the modified rule increases system performance, the federated learning logic 604 may retain the modified rule for the cooling policy of the hybrid cooling system 112. If the modified rule decreases system performance, the federated learning logic 604 may discard the modified rule from the cooling policy of the hybrid cooling system 112. The federated learning logic 604 may repeat this perturbation process in an iterative manner until it arrives at an optimal set of operating rules for the cooling policies 704.

The hybrid cooling controller 202 may also use one or more ML models 316 as previously described. The federated learning logic 604 of the hybrid cooling controller 202 may control, or participate in, training for the ML models 316, such as described with reference to logic diagram 800 and logic diagram 900. For example, the federated learning logic 604 may coordinate training between multiple servers, such as a server device of the edge compute platform 1 902, server device 934 of the edge compute platform 2 928, server device 940 of the edge compute platform E 930, and/or central server 950. For example, the federated learning logic 604 of the server device for the edge compute platform 1 902 may train a first ML model 948 for the hybrid cooling system 112 of a first federated system, such as the edge compute platform 1 902. The federated learning logic 604 may receive a second ML model 938 for a hybrid cooling system 112 from a second federated system, such as edge compute platform 2 928. The federated learning logic 604 may evaluate performance of the ML model 948 and the ML model 938 to obtain performance results. The federated learning logic 604 may determine whether to retain the first ML model 948 or the second ML model 938 to support inferencing operations of the hybrid cooling system 112 of the first federated system, such as edge compute platform 1 902, based on the performance results.

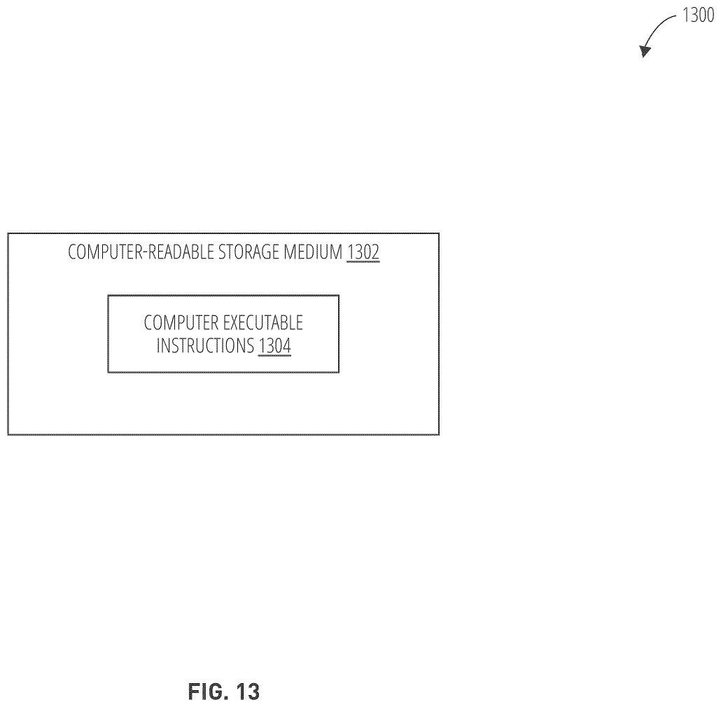

FIG. 13 illustrates an apparatus 1300. Apparatus 1300 comprises any non-transitory computer-readable storage medium 1302 or machine-readable storage medium, such as an optical, magnetic or semiconductor storage medium. In various embodiments, apparatus 1300 comprises an article of manufacture or a product. In some embodiments, the computer-readable storage medium 1302 stores computer executable instructions with which one or more processing devices or processing circuitry can execute. For example, computer executable instructions 1304 includes instructions to implement operations described with respect to any logic flows described herein. Examples of computer-readable storage medium 1302 or machine-readable storage medium include any tangible media capable of storing electronic data, including volatile memory or non-volatile memory, removable or non-removable memory, erasable or non-erasable memory, writeable or re-writeable memory, and so forth. Examples of computer executable instructions 1304 include any suitable type of code, such as source code, compiled code, interpreted code, executable code, static code, dynamic code, object-oriented code, visual code, and the like.

FIG. 14 illustrates an embodiment of a computing architecture 1400. Computing architecture 1400 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 1400 has a single processor with one core or more than one processor. Note that the term “processor” refers to a processor with a single core or a processor package with multiple processor cores. In at least one embodiment, the computing architecture 1400 is representative of the components of the system 1000. More generally, the computing architecture 1400 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 1400. For example, a component is, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server are a component. One or more components reside within a process and/or thread of execution, and a component is localized on one computer and/or distributed between two or more computers. Further, components are communicatively coupled to each other by various types of communications media to coordinate operations. The coordination involves the uni-directional or bi-directional exchange of information. For instance, the components communicate information in the form of signals communicated over the communications media. The information is implemented as signals allocated to various signal lines. In such allocations, each message is a signal. Further embodiments, however, alternatively employ data messages. Such data messages may be sent across various connections. Exemplary connections include parallel interfaces, serial interfaces, and bus interfaces.

As shown in FIG. 14, computing architecture 1400 comprises a system-on-chip (SoC) 1402 for mounting platform components. System-on-chip (SoC) 1402 is a point-to-point (P2P) interconnect platform that includes a first processor 1404 and a second processor 1406 coupled via a point-to-point interconnect 1470 such as an Ultra Path Interconnect (UPI). In other embodiments, the computing architecture 1400 is another bus architecture, such as a multi-drop bus. Furthermore, each of processor 1404 and processor 1406 are processor packages with multiple processor cores including core(s) 1408 and core(s) 1410, respectively. While the computing architecture 1400 is an example of a two-socket (2S) platform, other embodiments include more than two sockets or one socket. For example, some embodiments include a four-socket (4S) platform or an eight-socket (8S) platform. Each socket is a mount for a processor and may have a socket identifier. Note that the term platform refers to a motherboard with certain components mounted such as the processor 1404 and chipset 1432. Some platforms include additional components and some platforms include sockets to mount the processors and/or the chipset. Furthermore, some platforms do not have sockets (e.g. SoC, or the like). Although depicted as a SoC 1402, one or more of the components of the SoC 1402 are included in a single die package, a multi-chip module (MCM), a multi-die package, a chiplet, a bridge, and/or an interposer. Therefore, embodiments are not limited to a SoC.

The processor 1404 and processor 1406 are any commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures are also employed as the processor 1404 and/or processor 1406. Additionally, the processor 1404 need not be identical to processor 1406.

Processor 1404 includes an integrated memory controller (IMC) 1420 and point-to-point (P2P) interface 1424 and P2P interface 1428. Similarly, the processor 1406 includes an IMC 1422 as well as P2P interface 1426 and P2P interface 1430. IMC 1420 and IMC 1422 couple the processor 1404 and processor 1406, respectively, to respective memories (e.g., memory 1416 and memory 1418). Memory 1416 and memory 1418 are portions of the main memory (e.g., a dynamic random-access memory (DRAM)) for the platform such as double data rate type 4 (DDR4) or type 5 (DDR5) synchronous DRAM (SDRAM). In the present embodiment, the memory 1416 and the memory 1418 locally attach to the respective processors (i.e., processor 1404 and processor 1406). In other embodiments, the main memory couple with the processors via a bus and shared memory hub. Processor 1404 includes registers 1412 and processor 1406 includes registers 1414.

Computing architecture 1400 includes chipset 1432 coupled to processor 1404 and processor 1406. Furthermore, chipset 1432 are coupled to storage device 1450, for example, via an interface (I/F) 1438. The I/F 1438 may be, for example, a Peripheral Component Interconnect-enhanced (PCIe) interface, a Compute Express Link® (CXL) interface, or a Universal Chiplet Interconnect Express (UCIe) interface. Storage device 1450 stores instructions executable by circuitry of computing architecture 1400 (e.g., processor 1404, processor 1406, GPU 1448, accelerator 1454, vision processing unit 1456, or the like). For example, storage device 1450 can store instructions for the client device 1002, the client device 1006, the inferencing device 1004, the training device 1114, or the like.

Processor 1404 couples to the chipset 1432 via P2P interface 1428 and P2P 1434 while processor 1406 couples to the chipset 1432 via P2P interface 1430 and P2P 1436. Direct media interface (DMI) 1476 and DMI 1478 couple the P2P interface 1428 and the P2P 1434 and the P2P interface 1430 and P2P 1436, respectively. DMI 1476 and DMI 1478 is a high-speed interconnect that facilitates, e.g., eight Giga Transfers per second (GT/s) such as DMI 3.0. In other embodiments, the processor 1404 and processor 1406 interconnect via a bus.

The chipset 1432 comprises a controller hub such as a platform controller hub (PCH). The chipset 1432 includes a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (I2Cs), and the like, to facilitate connection of peripheral devices on the platform. In other embodiments, the chipset 1432 comprises more than one controller hub such as a chipset with a memory controller hub, a graphics controller hub, and an input/output (I/O) controller hub.

In the depicted example, chipset 1432 couples with a trusted platform module (TPM) 1444 and UEFI, BIOS, FLASH circuitry 1446 via I/F 1442. The TPM 1444 is a dedicated microcontroller designed to secure hardware by integrating cryptographic keys into devices. The UEFI, BIOS, FLASH circuitry 1446 may provide pre-boot code. The I/F 1442 may also be coupled to a network interface circuit (NIC) 1480 for connections off-chip.

Furthermore, chipset 1432 includes the I/F 1438 to couple chipset 1432 with a high-performance graphics engine, such as, graphics processing circuitry or a graphics processing unit (GPU) 1448. In other embodiments, the computing architecture 1400 includes a flexible display interface (FDI) (not shown) between the processor 1404 and/or the processor 1406 and the chipset 1432. The FDI interconnects a graphics processor core in one or more of processor 1404 and/or processor 1406 with the chipset 1432.

The computing architecture 1400 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication is a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network is used to connect computers to each other, to the Internet, and to wired networks (which use IEEE 802.3-related media and functions).

Additionally, accelerator 1454 and/or vision processing unit 1456 are coupled to chipset 1432 via I/F 1438. The accelerator 1454 is representative of any type of accelerator device (e.g., a data streaming accelerator, cryptographic accelerator, cryptographic co-processor, an offload engine, etc.). One example of an accelerator 1454 is the Intel® Data Streaming Accelerator (DSA). The accelerator 1454 is a device including circuitry to accelerate copy operations, data encryption, hash value computation, data comparison operations (including comparison of data in memory 1416 and/or memory 1418), and/or data compression. Examples for the accelerator 1454 include a USB device, PCI device, PCIe device, CXL device, UCIe device, and/or an SPI device. The accelerator 1454 also includes circuitry arranged to execute machine learning (ML) related operations (e.g., training, inference, etc.) for ML models. Generally, the accelerator 1454 is specially designed to perform computationally intensive operations, such as hash value computations, comparison operations, cryptographic operations, and/or compression operations, in a manner that is more efficient than when performed by the processor 1404 or processor 1406. Because the load of the computing architecture 1400 includes hash value computations, comparison operations, cryptographic operations, and/or compression operations, the accelerator 1454 greatly increases performance of the computing architecture 1400 for these operations.

The accelerator 1454 includes one or more dedicated work queues and one or more shared work queues (each not pictured). Generally, a shared work queue is configured to store descriptors submitted by multiple software entities. The software is any type of executable code, such as a process, a thread, an application, a virtual machine, a container, a microservice, etc., that share the accelerator 1454. For example, the accelerator 1454 is shared according to the Single Root I/O virtualization (SR-IOV) architecture and/or the Scalable I/O virtualization (S-IOV) architecture. Embodiments are not limited in these contexts. In some embodiments, software uses an instruction to atomically submit the descriptor to the accelerator 1454 via a non-posted write (e.g., a deferred memory write (DMWr)). One example of an instruction that atomically submits a work descriptor to the shared work queue of the accelerator 1454 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 1454. The dedicated work queue may accept job submissions via commands such as the movdir64b instruction.

Various I/O devices 1460 and display 1452 couple to the bus 1472, along with a bus bridge 1458 which couples the bus 1472 to a second bus 1474 and an I/F 1440 that connects the bus 1472 with the chipset 1432. In one embodiment, the second bus 1474 is a low pin count (LPC) bus. Various input/output (I/O) devices couple to the second bus 1474 including, for example, a keyboard 1462, a mouse 1464 and communication devices 1466.

Furthermore, an audio I/O 1468 couples to second bus 1474. Many of the I/O devices 1460 and communication devices 1466 reside on the system-on-chip (SoC) 1402 while the keyboard 1462 and the mouse 1464 are add-on peripherals. In other embodiments, some or all the I/O devices 1460 and communication devices 1466 are add-on peripherals and do not reside on the system-on-chip (SoC) 1402.

FIG. 15 illustrates a block diagram of an exemplary communications architecture 1500 suitable for implementing various embodiments as previously described. The communications architecture 1500 includes various common communications elements, such as a transmitter, receiver, transceiver, radio, network interface, baseband processor, antenna, amplifiers, filters, power supplies, and so forth. The embodiments, however, are not limited to implementation by the communications architecture 1500.

As shown in FIG. 15, the communications architecture 1500 includes one or more clients 1502 and servers 1504. The clients 1502 and the servers 1504 are operatively connected to one or more respective client data stores 1508 and server data stores 1510 that can be employed to store information local to the respective clients 1502 and servers 1504, such as cookies and/or associated contextual information.

The clients 1502 and the servers 1504 communicate information between each other using a communication framework 1506. The communication framework 1506 implements any well-known communications techniques and protocols. The communication framework 1506 is implemented as a packet-switched network (e.g., public networks such as the Internet, private networks such as an enterprise intranet, and so forth), a circuit-switched network (e.g., the public switched telephone network), or a combination of a packet-switched network and a circuit-switched network (with suitable gateways and translators).

The communication framework 1506 implements various network interfaces arranged to accept, communicate, and connect to a communications network. A network interface is regarded as a specialized form of an input output interface. Network interfaces employ connection protocols including without limitation direct connect, Ethernet (e.g., thick, thin, twisted pair 10/1000/1000 Base T, and the like), token ring, wireless network interfaces, cellular network interfaces, IEEE 802.11 network interfaces, IEEE 802.16 network interfaces, IEEE 802.20 network interfaces, and the like. Further, multiple network interfaces are used to engage with various communications network types. For example, multiple network interfaces are employed to allow for the communication over broadcast, multicast, and unicast networks. Should processing requirements dictate a greater amount speed and capacity, distributed network controller architectures are similarly employed to pool, load balance, and otherwise increase the communicative bandwidth required by clients 1502 and the servers 1504. A communications network is any one and the combination of wired and/or wireless networks including without limitation a direct interconnection, a secured custom connection, a private network (e.g., an enterprise intranet), a public network (e.g., the Internet), a Personal Area Network (PAN), a Local Area Network (LAN), a Metropolitan Area Network (MAN), an Operating Missions as Nodes on the Internet (OMNI), a Wide Area Network (WAN), a wireless network, a cellular network, and other communications networks.

Any of the above embodiments may be implemented as instructions stored on a non-transitory computer-readable storage medium and/or embodied as an apparatus with a memory and a circuitry configured to perform the actions described above. It is contemplated that these embodiments may be deployed individually to achieve improvements in resource requirements and library construction time. Alternatively, any of the embodiments may be used in combination with each other in order to achieve synergistic effects, some of which are noted above and elsewhere herein.

The various elements of the devices as previously described with reference to the figures include various hardware elements, software elements, or a combination of both. Examples of hardware elements include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements varies in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment are implemented by representative instructions stored on a machine-readable medium which represents various logic within the processor, which when read by a machine causes the machine to fabricate logic to perform the techniques described herein. Such representations, known as “intellectual property (IP) cores” are stored on a tangible, machine readable medium and supplied to various customers or manufacturing facilities to load into the fabrication machines that make the logic or processor. Some embodiments are implemented, for example, using a machine-readable medium or article which may store an instruction or a set of instructions that, when executed by a machine, causes the machine to perform a method and/or operations in accordance with the embodiments. Such a machine includes, for example, any suitable processing platform, computing platform, computing device, processing device, computing system, processing system, processing devices, computer, processor, or the like, and is implemented using any suitable combination of hardware and/or software. The machine-readable medium or article includes, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions include any suitable type of code, such as source code, compiled code, interpreted code, executable code, static code, dynamic code, encrypted code, and the like, implemented using any suitable high-level, low-level, object-oriented, visual, compiled and/or interpreted programming language.

As utilized herein, terms “component,” “system,” “interface,” and the like are intended to refer to a computer-related entity, hardware, software (e.g., in execution), and/or firmware. For example, a component is a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server is also a component. One or more components reside within a process, and a component is localized on one computer and/or distributed between two or more computers. A set of elements or a set of other components are described herein, in which the term “set” can be interpreted as “one or more.”

Further, these components execute from various computer readable storage media having various data structures stored thereon such as with a module, for example. The components communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component is an apparatus with specific functionality provided by mechanical parts operated by electric or electronic circuitry, in which the electric or electronic circuitry is operated by a software application or a firmware application executed by one or more processors. The one or more processors are internal or external to the apparatus and execute at least a part of the software or firmware application. As yet another example, a component is an apparatus that provides specific functionality through electronic components without mechanical parts; the electronic components include one or more processors there in to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description or the claims, such terms are intended to be inclusive in a manner similar to the term “comprising.” Additionally, in situations wherein one or more numbered items are discussed (e.g., a “first X”, a “second X”, etc.), in general the one or more numbered items may be distinct or they may be the same, although in some situations the context may indicate that they are distinct or that they are the same.

As used herein, the term “circuitry” may refer to, be part of, or include a circuit, an integrated circuit (IC), a monolithic IC, a discrete circuit, a hybrid integrated circuit (HIC), an Application Specific Integrated Circuit (ASIC), an electronic circuit, a logic circuit, a microcircuit, a hybrid circuit, a microchip, a chip, a chiplet, a chipset, a multi-chip module (MCM), a semiconductor die, a system on a chip (SoC), a processor (shared, dedicated, or group), a processor circuit, a processing circuit, or associated memory (shared, dedicated, or group) operably coupled to the circuitry that execute one or more software or firmware programs, a combinational logic circuit, or other suitable hardware components that provide the described functionality. In some embodiments, the circuitry is implemented in, or functions associated with the circuitry are implemented by, one or more software or firmware modules. In some embodiments, circuitry includes logic, at least partially operable in hardware. It is noted that hardware, firmware and/or software elements may be collectively or individually referred to herein as “logic” or “circuit.”

Some embodiments are described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately can be employed in combination with each other unless it is noted that the features are incompatible with each other.

Some embodiments are presented in terms of program procedures executed on a computer or network of computers. A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments are described using the expression “coupled” and “connected” along with their derivatives. These terms are not necessarily intended as synonyms for each other. For example, some embodiments are described using the terms “connected” and/or “coupled” to indicate that two or more elements are in direct physical or electrical contact with each other. The term “coupled”, however, also means that two or more elements are not in direct contact with each other, but yet still co-operate or interact with each other.

Various embodiments also relate to apparatus or systems for performing these operations. This apparatus is specially constructed for the required purpose or it comprises a general purpose computer as selectively activated or reconfigured by a computer program stored in the computer. The procedures presented herein are not inherently related to a particular computer or other apparatus. Various general purpose machines are used with programs written in accordance with the teachings herein, or it proves convenient to construct more specialized apparatus to perform the required method steps. The required structure for a variety of these machines are apparent from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The techniques described herein may be implemented with privacy safeguards to protect user privacy. Furthermore, the techniques described herein may be implemented with user privacy safeguards to prevent unauthorized access to personal data and confidential data. The training of the AI models described herein is executed to benefit all users fairly, without causing or amplifying unfair bias.

According to some embodiments, the techniques for the models described herein do not make inferences or predictions about individuals unless requested to do so through an input. According to some embodiments, the models described herein do not learn from and are not trained on user data without user authorization. In instances where user data is permitted and authorized for use in AI features and tools, it is done in compliance with a user's visibility settings, privacy choices, user agreement and descriptions, and the applicable law. According to the techniques described herein, users may have full control over the visibility of their content and who sees their content, as is controlled via the visibility settings. According to the techniques described herein, users may have full control over the level of their personal data that is shared and distributed between different AI platforms that provide different functionalities. According to the techniques described herein, users may choose to share personal data with different platforms to provide services that are more tailored to the users. In instances where the users choose not to share personal data with the platforms, the choices made by the users will not have any impact on their ability to use the services that they had access to prior to making their choice.

According to the techniques described herein, users may have full control over the level of access to their personal data that is shared with other parties. According to the techniques described herein, personal data provided by users may be processed to determine prompts when using a generative AI feature at the request of the user, but not to train generative AI models. In some embodiments, users may provide feedback while using the techniques described herein, which may be used to improve or modify the platform and products. In some embodiments, any personal data associated with a user, such as personal information provided by the user to the platform, may be deleted from storage upon user request. In some embodiments, personal information associated with a user may be permanently deleted from storage when a user deletes their account from the platform.

According to the techniques described herein, personal data may be removed from any training dataset that is used to train AI models. The techniques described herein may utilize tools for anonymizing member and customer data. For example, user's personal data may be redacted and minimized in training datasets for training AI models through delexicalisation tools and other privacy enhancing tools for safeguarding user data. The techniques described herein may minimize use of any personal data in training AI models, including removing and replacing personal data. According to the techniques described herein, notices may be communicated to users to inform how their data is being used and users are provided controls to opt-out from their data being used for training AI models.

According to some embodiments, tools are used with the techniques described herein to identify and mitigate risks associated with AI in all products and AI systems. In some embodiments, notices may be provided to users when AI tools are being used to provide features.

The following examples pertain to further embodiments, from which numerous permutations and configurations will be apparent.

Example 1. A method comprising: selecting a cooling system type from a set of cooling system types of a hybrid cooling system to cool an electronic component of an electronic device; generating a control directive to activate a cooling component of the cooling system type; and performing thermal management of the electronic component of the electronic device using the cooling component of the cooling system type.

Example 2. The method of any previous example, wherein the set of cooling system types comprise an air cooling system type or a liquid cooling system type.

Example 3. The method of any previous example, comprising: decoding sensor data from a sensor for the electronic component of the electronic device; and selecting the cooling system type from the set of cooling system types based on the sensor data.

Example 4. The method of any previous example, comprising: accessing a cooling policy for the hybrid cooling system, the cooling policy comprising a set of operating rules for the hybrid cooling system; and selecting the cooling system type from the set of cooling system types based on an operating rule of the cooling policy.

Example 5. The method of any previous example, comprising: accessing a cooling policy for the hybrid cooling system, the cooling policy comprising a set of operating rules for the hybrid cooling system; selecting a different cooling system type from the set of cooling system types based on an operating rule of the cooling policy; generating a control directive to activate a cooling component of the different cooling system type; and performing thermal management of the electronic component of the electronic device using the cooling component of the different cooling system type.

Example 6. The method of any previous example, comprising: receiving a set of system metrics for the hybrid cooling system; decoding a set of sensor data from a set of sensors for multiple electronic devices cooled by the hybrid cooling system according to a cooling policy; comparing the set of sensor data to the set of system metrics to obtain a set of residual values; and selecting a different cooling system type from the set of cooling system types of the hybrid cooling system to cool the electronic component of the electronic device based on the residual values.

Example 7. The method of any previous example, comprising: receiving a set of system metrics for the hybrid cooling system; modifying a rule from a cooling policy for the hybrid cooling system; decoding a set of sensor data from a set of sensors for multiple electronic devices cooled by the hybrid cooling system according to the modified rule of the cooling policy; comparing the set of sensor data to the set of system metrics to obtain a set of residual values; and determining whether to retain or discard the modified rule of the cooling policy for the hybrid cooling system based on the residual values.

Example 8. The method of any previous example, comprising: training a first machine learning model for the hybrid cooling system of a first federated system; receiving a second machine learning model for a hybrid cooling system from a second federated system; evaluating performance of the first machine learning model and the second machine learning model to obtain performance results; and determining whether to retain or retrain the first machine learning model or the second machine learning model to support inferencing operations of the hybrid cooling system of the first federated system based on the performance results.

Example 9. A computing apparatus comprising: circuitry; and a memory storing instructions that, when executed by the circuitry, causes the circuitry to: select a cooling system type from a set of cooling system types of a hybrid cooling system to cool an electronic component of an electronic device; generate a control directive to activate a cooling component of the cooling system type; and perform thermal management of the electronic component of the electronic device using the cooling component of the cooling system type.

Example 10. The computing apparatus of any previous example, wherein the set of cool system types comprise an air cooling system type or a liquid cooling system type.

Example 11. The computing apparatus of any previous example, the circuitry to: decode sensor data from a sensor for the electronic component of the electronic device; and select the cooling system type from the set of cooling system types based on the sensor data.

Example 12. The computing apparatus of any previous example, the circuitry to: access a cooling policy for the hybrid cooling system, the cooling policy comprising a set of operating rules for the hybrid cooling system; and select the cooling system type from the set of cooling system types based on an operating rule of the cooling policy.

Example 13. The computing apparatus of any previous example, the circuitry to: access a cooling policy for the hybrid cooling system, the cooling policy comprising a set of operating rules for the hybrid cooling system; select a different cooling system type from the set of cooling system types based on an operating rule of the cooling policy; generate a control directive to activate a cooling component of the different cooling system type; and perform thermal management of the electronic component of the electronic device using the cooling component of the different cooling system type.

Example 14. The computing apparatus of any previous example, the circuitry to: receive a set of system metrics for the hybrid cooling system; decode a set of sensor data from a set of sensors for multiple electronic devices cooled by the hybrid cooling system according to a cooling policy; compare the set of sensor data to the set of system metrics to obtain a set of residual values; and select one or more different cooling system types from the set of cooling system types of the hybrid cooling system to cool the electronic component of the electronic device based on the residual values.

Example 15. The computing apparatus of any previous example, the circuitry to: receive a set of system metrics for the hybrid cooling system; modify a rule from a cooling policy for the hybrid cooling system; decode a set of sensor data from a set of sensors for multiple electronic devices cooled by the hybrid cooling system according to the modified rule of the cooling policy; compare the set of sensor data to the set of system metrics to obtain a set of residual values; and determine whether to retain, update, or discard the modified rule of the cooling policy for the hybrid cooling system based on the residual values.

Example 16. A non-transitory computer-readable storage medium, the computer-readable storage medium including instructions that when executed by circuitry, cause the circuitry to: select a cooling system type from a set of cooling system types of a hybrid cooling system to cool an electronic component of an electronic device; generate a control directive to activate a cooling component of the cooling system type; and perform thermal management of the electronic component of the electronic device using the cooling component of the cooling system type.

Example 17. The computer-readable storage medium of any previous example, wherein the set of cool system types comprise an air cooling system type or a liquid cooling system type.

Example 18. The computer-readable storage medium of any previous example, comprising instructions that when executed by circuitry, cause the circuitry to: decode sensor data from a sensor for the electronic component of the electronic device; and select the cooling system type from the set of cooling system types based on the sensor data.

Example 19. The computer-readable storage medium of any previous example, comprising instructions that when executed by circuitry, cause the circuitry to: access a cooling policy for the hybrid cooling system, the cooling policy comprising a set of operating rules for the hybrid cooling system; and select the cooling system type from the set of cooling system types based on an operating rule of the cooling policy.

Example 20. The computer-readable storage medium of any previous example, comprising instructions that when executed by circuitry, cause the circuitry to: access a cooling policy for the hybrid cooling system, the cooling policy comprising a set of operating rules for the hybrid cooling system; select a different cooling system type from the set of cooling system types based on an operating rule of the cooling policy; generate a control directive to activate a cooling component of the different cooling system type; and perform thermal management of the electronic component of the electronic device using the cooling component of the different cooling system type.

Example 21. An apparatus, comprising: means for selecting a cooling system type from a set of cooling system types of a hybrid cooling system to cool an electronic component of an electronic device; means for generating a control directive to activate a cooling component of the cooling system type; and means for performing thermal management of the electronic component of the electronic device using the cooling component of the cooling system type.

Example 22. The apparatus of any previous example, wherein the set of cooling system types comprise an air cooling system type or a liquid cooling system type.

Example 23. The apparatus of any previous example, comprising: means for decoding sensor data from a sensor for the electronic component of the electronic device; and means for selecting the cooling system type from the set of cooling system types based on the sensor data.

Example 24. The apparatus of any previous example, comprising: means for accessing a cooling policy for the hybrid cooling system, the cooling policy comprising a set of operating rules for the hybrid cooling system; and means for selecting the cooling system type from the set of cooling system types based on an operating rule of the cooling policy.

Example 25. The apparatus of any previous example, comprising: means for accessing a cooling policy for the hybrid cooling system, the cooling policy comprising a set of operating rules for the hybrid cooling system; means for selecting a different cooling system type from the set of cooling system types based on an operating rule of the cooling policy; means for generating a control directive to activate a cooling component of the different cooling system type; and means for performing thermal management of the electronic component of the electronic device using the cooling component of the different cooling system type.

Example 26. The apparatus of any previous example, comprising: means for receiving a set of system metrics for the hybrid cooling system; means for decoding a set of sensor data from a set of sensors for multiple electronic devices cooled by the hybrid cooling system according to a cooling policy; means for comparing the set of sensor data to the set of system metrics to obtain a set of residual values; and means for selecting a different cooling system type from the set of cooling system types of the hybrid cooling system to cool the electronic component of the electronic device based on the residual values.

Example 27. The apparatus of any previous example, comprising: means for receiving a set of system metrics for the hybrid cooling system; means for modifying a rule from a cooling policy for the hybrid cooling system; means for decoding a set of sensor data from a set of sensors for multiple electronic devices cooled by the hybrid cooling system according to the modified rule of the cooling policy; means for comparing the set of sensor data to the set of system metrics to obtain a set of residual values; and means for determining whether to retain or discard the modified rule of the cooling policy for the hybrid cooling system based on the residual values.

Example 28. The apparatus of any previous example, comprising: means for training a first machine learning model for the hybrid cooling system of a first federated system; means for receiving a second machine learning model for a hybrid cooling system from a second federated system; means for evaluating performance of the first machine learning model and the second machine learning model to obtain performance results; and means for determining whether to retain or retrain the first machine learning model or the second machine learning model to support inferencing operations of the hybrid cooling system of the first federated system based on the performance results.

What is claimed is:

1. A method comprising:
selecting a cooling system type from a set of cooling system types of a hybrid cooling system to cool an electronic component of an electronic device;
generating a control directive to activate a cooling component of the cooling system type; and
performing thermal management of the electronic component of the electronic device using the cooling component of the cooling system type.

2. The method of claim 1, wherein the set of cooling system types comprise an air cooling system type or a liquid cooling system type.

3. The method of claim 1, comprising:
decoding sensor data from a sensor for the electronic component of the electronic device; and
selecting the cooling system type from the set of cooling system types based on the sensor data.

4. The method of claim 1, comprising:
accessing a cooling policy for the hybrid cooling system, the cooling policy comprising a set of operating rules for the hybrid cooling system; and
selecting the cooling system type from the set of cooling system types based on an operating rule of the cooling policy.

5. The method of claim 1, comprising:
accessing a cooling policy for the hybrid cooling system, the cooling policy comprising a set of operating rules for the hybrid cooling system;
selecting a different cooling system type from the set of cooling system types based on an operating rule of the cooling policy;
generating a control directive to activate a cooling component of the different cooling system type; and
performing thermal management of the electronic component of the electronic device using the cooling component of the different cooling system type.

6. The method of claim 1, comprising:
receiving a set of system metrics for the hybrid cooling system;
decoding a set of sensor data from a set of sensors for multiple electronic devices cooled by the hybrid cooling system according to a cooling policy;
comparing the set of sensor data to the set of system metrics to obtain a set of residual values; and
selecting a different cooling system type from the set of cooling system types of the hybrid cooling system to cool the electronic component of the electronic device based on the residual values.

7. The method of claim 1, comprising:
receiving a set of system metrics for the hybrid cooling system;
modifying a rule from a cooling policy for the hybrid cooling system;
decoding a set of sensor data from a set of sensors for multiple electronic devices cooled by the hybrid cooling system according to the modified rule of the cooling policy;
comparing the set of sensor data to the set of system metrics to obtain a set of residual values; and
determining whether to retain or discard the modified rule of the cooling policy for the hybrid cooling system based on the residual values.

8. The method of claim 1, comprising:
training a first machine learning model for the hybrid cooling system of a first federated system;
receiving a second machine learning model for a hybrid cooling system from a second federated system;
evaluating performance of the first machine learning model and the second machine learning model to obtain performance results; and
determining whether to retain or retrain the first machine learning model or the second machine learning model to support inferencing operations of the hybrid cooling system of the first federated system based on the performance results.

9. A computing apparatus comprising:
circuitry; and
a memory storing instructions that, when executed by the circuitry, causes the circuitry to:
select a cooling system type from a set of cooling system types of a hybrid cooling system to cool an electronic component of an electronic device;
generate a control directive to activate a cooling component of the cooling system type; and
perform thermal management of the electronic component of the electronic device using the cooling component of the cooling system type.

10. The computing apparatus of claim 9, wherein the set of cool system types comprise an air cooling system type or a liquid cooling system type.

11. The computing apparatus of claim 9, the circuitry to:
decode sensor data from a sensor for the electronic component of the electronic device; and
select the cooling system type from the set of cooling system types based on the sensor data.

12. The computing apparatus of claim 9, the circuitry to:
access a cooling policy for the hybrid cooling system, the cooling policy comprising a set of operating rules for the hybrid cooling system; and
select the cooling system type from the set of cooling system types based on an operating rule of the cooling policy.

13. The computing apparatus of claim 9, the circuitry to:
access a cooling policy for the hybrid cooling system, the cooling policy comprising a set of operating rules for the hybrid cooling system;
select a different cooling system type from the set of cooling system types based on an operating rule of the cooling policy;
generate a control directive to activate a cooling component of the different cooling system type; and
perform thermal management of the electronic component of the electronic device using the cooling component of the different cooling system type.

14. The computing apparatus of claim 9, the circuitry to:
receive a set of system metrics for the hybrid cooling system;
decode a set of sensor data from a set of sensors for multiple electronic devices cooled by the hybrid cooling system according to a cooling policy;
compare the set of sensor data to the set of system metrics to obtain a set of residual values; and
select one or more different cooling system types from the set of cooling system types of the hybrid cooling system to cool the electronic component of the electronic device based on the residual values.

15. The computing apparatus of claim 9, the circuitry to:
receive a set of system metrics for the hybrid cooling system;
modify a rule from a cooling policy for the hybrid cooling system;
decode a set of sensor data from a set of sensors for multiple electronic devices cooled by the hybrid cooling system according to the modified rule of the cooling policy;
compare the set of sensor data to the set of system metrics to obtain a set of residual values; and
determine whether to retain, update, or discard the modified rule of the cooling policy for the hybrid cooling system based on the residual values.

16. A non-transitory computer-readable storage medium, the computer-readable storage medium including instructions that when executed by circuitry, cause the circuitry to:
select a cooling system type from a set of cooling system types of a hybrid cooling system to cool an electronic component of an electronic device;
generate a control directive to activate a cooling component of the cooling system type; and
perform thermal management of the electronic component of the electronic device using the cooling component of the cooling system type.

17. The computer-readable storage medium of claim 16, wherein the set of cool system types comprise an air cooling system type or a liquid cooling system type.

18. The computer-readable storage medium of claim 16, comprising instructions that when executed by circuitry, cause the circuitry to:
decode sensor data from a sensor for the electronic component of the electronic device; and
select the cooling system type from the set of cooling system types based on the sensor data.

19. The computer-readable storage medium of claim 16, comprising instructions that when executed by circuitry, cause the circuitry to:
access a cooling policy for the hybrid cooling system, the cooling policy comprising a set of operating rules for the hybrid cooling system; and
select the cooling system type from the set of cooling system types based on an operating rule of the cooling policy.

20. The computer-readable storage medium of claim 16, comprising instructions that when executed by circuitry, cause the circuitry to:
access a cooling policy for the hybrid cooling system, the cooling policy comprising a set of operating rules for the hybrid cooling system;
select a different cooling system type from the set of cooling system types based on an operating rule of the cooling policy;
generate a control directive to activate a cooling component of the different cooling system type; and
perform thermal management of the electronic component of the electronic device using the cooling component of the different cooling system type.
